(19) United States
(12) Patent Application Publication
(10) Pub. No.: US 2026/0223670 A1
(43) Pub. Date: Jul. 30, 2026

(54) DUAL-GEOMETRY PEDESTAL FOR COOLING SYSTEM

(71) Applicant: MELLANOX TECHNOLOGIES, LTD., Yokneam (IL)

(72) Inventors: Michael Dolinski, Kiryat Ata (IL); Yogev Buzaglo, Kiryat Ata (IL); Eli Zatulovski, Nesher (IL); Tom Shay, Kfar Tavor (IL); Beeri Halachmi, Kohav Yair (IL); Rachel Ruvel, Qriyat Ata (IL); Shlomi Yaacov, Tirat Carmel (IL); Rayan Halabi, Haifa (IL); Rom Becker, Ramat Yishai (IL); David Azoulay, Petah Tikva (IL); Kfir Katz, Tivon (IL)

(21) Appl. No.: 19/213,768

(22) Filed: May 20, 2025

Related U.S. Application Data
(60) Provisional application No. 63/751,721, filed on Jan. 30, 2025.

(51) Int. Cl. H01L 23/367; H01L 23/46

(52) U.S. Cl. CPC H10W 40/22; H10W 40/40

(57) ABSTRACT

Systems are disclosed that support improved cooling of processing units and other semiconductor dies in a datacenter or elsewhere. An example of such a system may include a pedestal configured to support a semiconductor package, the pedestal having a first geometry with a contact surface and a second geometry with a pressure surface, where the pressure surface is offset from the contact surface and applies pressure to the semiconductor package to mitigate the negative effects on heat transfer of thermo-mechanical warpage of the semiconductor package.

### CROSS-REFERENCE TO RELATED APPLICATION

The present application claims the benefit of and priority, under 35 U.S.C. § 119, to U.S. Provisional Application Ser. No. 63/751,721, filed Jan. 30, 2025, entitled “PRESSURE-OPTIMIZED THERMAL INTERFACE” the entire disclosure of which is hereby incorporated herein by reference, in its entirety, for all that it teaches and for all purposes.

### FIELD OF THE DISCLOSURE

Embodiments of the present disclosure relate generally to thermal solutions for computing hardware, and more specifically to cooling components used in a datacenter.

### BACKGROUND

As datacenters continue to operate at higher speeds (e.g., 100Gb and beyond) and semiconductor dies grow larger in response to increased processing requirements, the thermal demands on the datacenter components increase as well. Heat generation in datacenters occurs primarily due to the electricity used by servers, storage devices, and other hardware components, where nearly all the consumed energy is converted into heat as a byproduct of processing data, essentially meaning that for every watt of electricity used, a watt of heat is produced. The heat requires careful management; otherwise, components of the datacenter may fail under extreme thermal loads. For instance, processing units can generate heat during operation, which can result in reduced processing power and, in some cases, the failure of those processing units as well as the failure of system components connected thereto.

### GENERAL DESCRIPTION

Embodiments of the present disclosure aim to address at least some issues associated with thermal loads in a datacenter, and more specifically with thermal loads generated by processing units. As graphics processing unit (GPU) packages increase in size and power, so too does the thermo-mechanical warpage of the package resulting from the use of different materials with different coefficients of thermal expansion (CTEs) within the package. (The same is true of central processing unit (CPU) packages, parallel processing unit (PPU) packages, and other processing unit packages. Throughout the present disclosure, it should be understood that references to GPUs and GPU packages apply also to other types of processing units and processing unit packages, respectively, including any other type of processing unit and processing unit package described herein.) The difference between the flattest and most warped states of these devices can be several hundred microns.

GPUs and other processing units and related components are manufactured from a variety of materials, which may include, for example, silicon, FR4 (a flame-retardant, glass-reinforced epoxy resin laminate material), aluminum, copper, and tungsten. These materials, however, have disparate CTEs. For example, copper expands approximately five times more than silicon: the coefficient of thermal expansion (CTE) of copper is 16-16.7 ppm, while that of silicon is 3-5 ppm (https://www.engineeringtoolbox.com/linear-expansion-coefficients-d_95.html).

Among the challenges associated with the continued use of copper—and/or other materials with a CTE higher or lower than that of silicon—in larger and higher-power GPUs is that thermal cycling induces die warpage due to the CTE mismatch. More specifically, during thermal operation, the GPU package substrate experiences temperature-induced planarization due to the CTE mismatch between FR4, the integrated circuit package, and silicon materials.

Semiconductor dies are often joined to cold plates or other heat-dissipating devices via a thermal interface material (TIM), which improves heat transfer away from the silicon package. Uniform heat transfer is best achieved when the thickness of the TIM is also uniform. However, the thermal cycling-induced warpage described above tends to increase the gap between the middle of the semiconductor die and the cold plate pedestal, leading to TIM thickening (or even separation) at the die center. This inhibits the transfer of heat near the die center and results in a non-optimal heat transfer profile. At room temperature, the pressure between the heat sink and the die is even. However, at high temperatures, the pressure in the middle decreases, leading to thermal shutdown. Moreover, the loss of pressure in the die center causes thermal shutdown.

A need exists, then, to ensure a more uniform TIM thickness, and thus heat transfer profile, between a silicon package and an attached cold plate notwithstanding warpage of the silicon package over time due to thermal cycling.

Embodiments of the present disclosure provide a solution to this problem, thus enabling adequate thermal management even for larger, higher-powered semiconductor dies. More specifically, embodiments of the present disclosure provide an approach to address the above-noted CTE mis-match issues by optimizing pressure distribution across the semiconductor package. The improved pressure distribution helps to maintain uniform TIM contact and thickness across the contact area with the semiconductor package, thereby enhancing thermal performance of the overall system.

Embodiments of the present disclosure relate to a system having a cooling solution with a dual-geometry pedestal design. The pedestal design, in some embodiments, may include an elevated central region extending from a base pedestal surface. The base pedestal surface may correspond to a flat or convex surface.

Embodiments of the present disclosure contemplate a pedestal geometry that maintains a substantially concentrated pressure at a center of a semiconductor/silicon package through the elevated central region. Concentrating pressure in this way effectively counteracts thermal-mechanical deformation and ensures substantially consistent thermal contact across operational temperatures. The pedestal geometry helps maintain the necessary pressure, preventing thermal shutdown and ensuring the system works properly.

Traditional cooling solutions utilize a single-plane flat pedestal surface, whereas embodiments of the present disclosure implement an elevated center “coin” having a pressure surface offset from the top of a larger contact surface, which contact surface may be flat or convex. While conventional approaches rely on material properties and rigid core materials to manage warpage, embodiments disclosed herein utilize a geometric modification to actively control pressure distribution and maintain central contact on the lid.

A system according to embodiments of the present disclosure may comprise a pedestal configured to support a semiconductor package, where the pedestal is part of a cold plate and comprises a first geometry having a contact surface (e.g., a surface that supports and transfers heat away from the semiconductor package), and a second geometry having a pressure surface (e.g., a surface that exerts pressure on portion of the semiconductor package to improve heat transfer therefrom, as described herein) that is offset from (e.g., raised above) the contact surface. The pedestal is a heat sink pedestal which increases thermal performance and may contact the die, the silicon or the package. It may also be possible to include another plate on top of the heat sink pedestal, which could further improve the thermal performance of the heat sink (e.g., improving the thermal impact by approximately 2 degrees Celsius).

A system according to other embodiments of the present disclosure may comprise a cooling system that, in turn, includes a plurality of cooling elements and a plate in thermal communication with the plurality of cooling elements. The plate may be a soldered plate and include a contact surface and a pressure surface on a protrusion that extends from the contact surface.

A system according to still other embodiments of the present disclosure may be a dual-geometry cooling plate that includes a first portion having a first geometry and a contact surface, and a second portion that includes a second geometry and a pressure surface offset from the contact surface. The first portion and the second portion may form an integral cooling plate. The second portion may be soldered on top of the pedestal plate

In some embodiments, a cooling system is provided that includes: a pedestal to support a semiconductor package, the pedestal comprising: a first geometry having a contact surface; and at least one second geometry having a pressure surface, the pressure surface offset from the contact surface.

In some aspects, the pedestal comprises two second geometries, each having a pressure surface offset from the contact surface.

In some aspects, the contact surface comprises a convex or concave surface.

In some aspects, the pressure surface is parallel to the contact surface.

In some aspects, the pressure surface is raised above the contact surface.

In some aspects, the pressure surface comprises a convex or concave surface.

In some aspects, the contact surface has a square perimeter.

In some aspects, the contact surface has a rectangular perimeter.

In some aspects, the pressure surface has a circular perimeter.

In some aspects, the pressure surface has a square perimeter.

In some aspects, the pressure surface has a rectangular perimeter.

In some aspects, the pressure surface has a pressure surface area, the contact surface has a contact surface area, and the pressure surface area is between two percent and fifteen percent of the contact surface area.

In some aspects, the pressure surface area is between 2 and 2.5 percent of the contact surface area. As a more specific example, the pressure surface area is between 2.1 and 2.3 percent of the contact surface area.

In some aspects, the pressure surface is offset from the contact surface by no more than 100 microns.

In some aspects, the pressure surface is offset from the contact surface by no more than fifty microns.

In some aspects, the pressure surface is offset from the contact surface by no more than 35 microns.

In some aspects, the pressure surface is offset from the contact surface by more than 25 microns.

In some aspects, the first geometry is a right prism.

In some aspects, the second geometry is a cylinder.

In some aspects, the second geometry is centrally located relative to the first geometry.

In some aspects, the pressure surface includes a midpoint that is equidistant from opposite points on a perimeter of the contact surface.

In some aspects, the second geometry extends from the first geometry.

In some aspects, the contact surface and the pressure surface are covered in a thermal interface material.

In some aspects, the first geometry is similar to the second geometry.

In some aspects, the first geometry is not similar to the second geometry.

Another embodiment of a cooling system is provided that includes: a plurality of cooling elements; and a plate in thermal communication with at least one of the plurality of cooling elements, the plate including: a contact surface; and a pressure surface on a protrusion extending from the contact surface.

In some aspects, a height of the pressure surface above the contact surface is less than five percent of a height of the plate.

In some aspects, a height of the pressure surface above the contact surface is less than two percent of a height of the plate.

In some aspects, the contact surface has a square geometry and the pressure surface has a circular geometry.

In some aspects, the plate is right prismatic and the protrusion is cylindrical.

In some aspects, the cooling system further includes: a semiconductor package mounted to the plate; and a thermal interface material positioned between the semiconductor package and the plate.

In some aspects, a pressure applied to the semiconductor package by the pressure surface substantially counteracts thermal-mechanical deformations in the semiconductor package when the semiconductor package is in use.

In some aspects, the pressure surface maintains central contact with the semiconductor package during use thereof.

In some aspects, thermal-mechanical deformation of the semiconductor package during use thereof does not break thermal contact between the pressure surface and the semiconductor package.

In some aspects, the pressure surface creates a pressure distribution that ensures substantially continuous thermal contact between the semiconductor package and the plate during operation of the semiconductor package.

In another embodiment, a dual-geometry cooling plate is provided that includes: a first portion having a first geometry and a contact surface; and a second portion having a second geometry and a pressure surface offset from the contact surface, where the first portion and the second portion form an integral cooling plate.

In some aspects, milling is used to generate the second geometry.

In some aspects, the first geometry is a plate having a thickness of no more than 2000 microns, and the second geometry is a cylinder having a height of no more than 50 microns.

In some aspects, the second portion extends from the first portion.

In some aspects, the first geometry is different than the second geometry.

Any aspect in combination with any one or more other aspects.

Any one or more of the features disclosed herein.

Any one or more of the features as substantially disclosed herein.

Any one or more of the features as substantially disclosed herein in combination with any one or more other features as substantially disclosed herein.

Any one of the aspects/features/implementations in combination with any one or more other aspects/features/implementations.

Use of any one or more of the aspects or features as disclosed herein.

It is to be appreciated that any feature described herein can be claimed in combination with any other feature(s) as described herein, regardless of whether the features come from the same described implementation.

The details of one or more aspects of the disclosure are set forth in the accompanying drawings and the description below. Other features, objects, and advantages of the techniques described in this disclosure will be apparent from the description and drawings, and from the claims.

Numerous additional features and advantages of the present disclosure will become apparent to those skilled in the art upon consideration of the implementation descriptions provided hereinbelow.

Additional features and advantages are described herein and will be apparent from the following Description and the figures.

### BRIEF DESCRIPTION OF THE SEVERAL VIEWS OF THE DRAWINGS

Having thus described the disclosure in general terms, reference will now be made to the accompanying drawings, which are not necessarily drawn to scale:

FIG. 1 is a perspective view of a cooling system according to at least some embodiments of the present disclosure;

FIG. 2 is a perspective view of a portion of the cooling system of FIG. 1 according to at least some embodiments of the present disclosure;

FIG. 3 is a perspective view of another portion of the cooling system of FIG. 1 according to at least some embodiments of the present disclosure;

FIG. 4A is a perspective view of a section of the cooling system of FIG. 1 according to at least some embodiments of the present disclosure;

FIG. 4B is a perspective view of a section of a cooling system, similar to FIG. 4A but showing a variation according to at least some embodiments of the present disclosure;

FIG. 5 is an elevation view of a portion of a cooling system according to at least some embodiments of the present disclosure;

FIG. 6 is an elevation view of a portion of a cooling system according to at least some embodiments of the present disclosure;

FIG. 7 is a block diagram of a portion of a semiconductor die cooling arrangement according to at least some embodiments of the present disclosure;

FIG. 8 is an illustration of a portion of a dual-geometry cooling system according to at least some embodiments of the present disclosure;

FIG. 9 is a series of heat maps comparing heat transfer results achieved using an embodiment of the present disclosure to heat transfer results achieved without using embodiments of the present disclosure;

FIG. 10 is a block diagram illustrating a computer system according to at least some embodiments of the present disclosure;

FIG. 11 is a block diagram illustrating further details of a datacenter and components thereof according to at least some embodiments of the present disclosure;

FIG. 12 is a block diagram of a system according to at least some embodiments of the present disclosure;

FIG. 13 depicts a datacenter according to at least some embodiments of the present disclosure;

FIG. 14 depicts a liquid-cooled server rack according to at least some embodiments of the present disclosure;

FIGS. 15A-15D depict block diagrams showing aspects of a neural network-enabled approach to liquid cooling of racks at a data center level according to at least some embodiments of the present disclosure;

FIG. 16 depicts a block diagram of a system according to at least some embodiments of the present disclosure; and

FIG. 17 depicts a block diagram of a computing environment according to at least some embodiments of the present disclosure.

Like reference numbers and designations in the various drawings may indicate like elements.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It is understood that various changes may be made in the function and arrangement of elements without departing from the spirit and scope of the appended claims.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

Various aspects of the present disclosure will be described herein with reference to drawings that are schematic illustrations of idealized configurations.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

The present disclosure will be described more fully hereinafter with reference to the accompanying figures in which some but not all embodiments of the disclosures are shown. Indeed, the present disclosure may be embodied in many different forms and should not be construed as limited to the embodiments set forth herein.

Like numbers refer to like elements throughout. As used herein, terms such as “front,” “rear,” “top,” etc. are used in the examples provided below to describe the position of certain components or portions of components in an installed and operational configuration. As used herein, the term “module” encompasses hardware, software and/or firmware configured to perform one or more particular functions, including but not limited to conversion between electrical and optical signals and transmission of the same. As would be evident to one of ordinary skill in the art in light of the present disclosure, the term “substantially” indicates that the referenced element or associated description is accurate to within applicable engineering tolerances.

Embodiments of the present disclosure are contemplated to be deployed in a datacenter environment. While embodiments will be described in connection with certain examples of datacenter environments, it should be appreciated that embodiments of the present disclosure are not so limited. Indeed, embodiments of the present disclosure may be deployed in any number of environments, including a datacenter environment or any other suitable environment that requires the management of thermal loads generated by computing components.

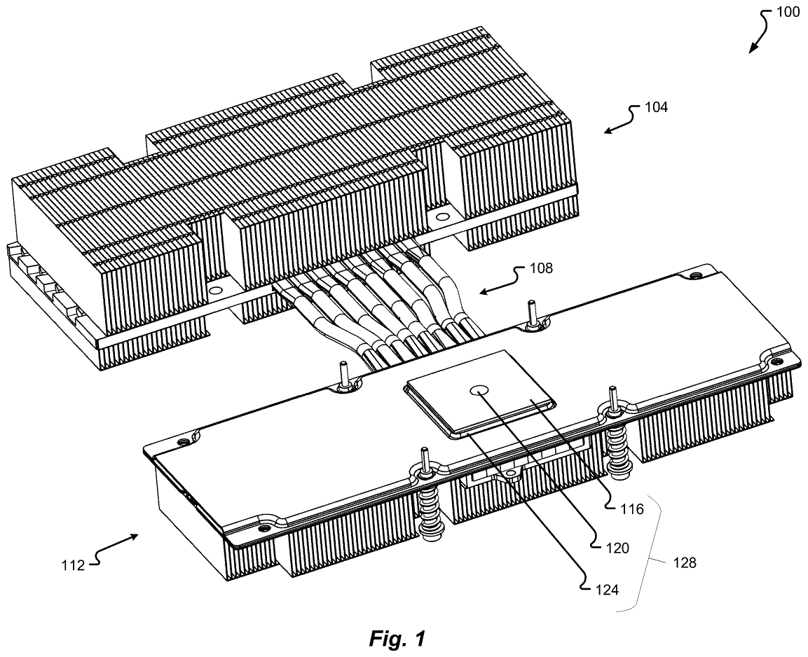

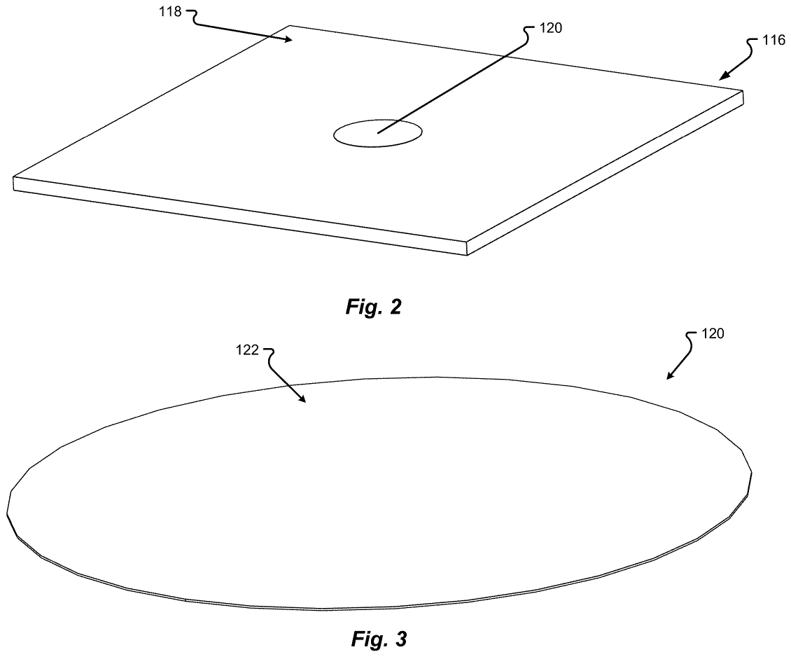

Illustrative datacenter environments and components useful for understanding the present disclosure are shown and will now be described with reference to FIGS. 1 through 17.

FIG. 1 shows a perspective view of a system 100, which will be described in accordance with at least some embodiments of the present disclosure. The system 100 has three primary portions 104, 108, and 112, each of which comprises one or more cooling elements, such as a heat transfer fluid reservoir, a heat exchanger (which may include, for example, a radiator comprising a plurality of fins in thermal communication with a heat transfer reservoir or conduit), and/or heat transfer fluid conduits that enable the circulation of heat transfer fluid between or among heat transfer fluid reservoirs and/or through one or more heat exchangers.

Referring now to FIGS. 1-4A, the primary portion 112 includes a pedestal 128 comprising a raised portion 124, a first geometry 116, and a second geometry 120. The pedestal 128 is configured to support and cool a semiconductor die during use thereof, and is specifically intended to facilitate the extraction of heat from the semiconductor die, the transfer of that heat away from the semiconductor die, and the eventual dissipation of that heat into the surrounding environment. The term semiconductor die, as used herein, encompasses a GPU, a CPU, a QPU, a PPU, an ASIC, and any other processing unit or similar silicon package that generates heat during use.

The raised portion 124 of the pedestal 128 houses, for example, a heat transfer fluid reservoir, one or more heat transfer fluid conduits, and/or a heat exchanger, each configured to extract heat from the first geometry 116 and transfer that heat back through the primary portions 112, 108, and 104 of the cooling system 100 to facilitate dissipation thereof. The first geometry 116 comprises a contact surface 118 configured to support, at least in part, a semiconductor die or other silicon package. The second geometry 120 comprises a pressure surface 122 that is also configured to support, at least in part, a semiconductor die, but that is further configured to apply pressure to the semiconductor die to counteract the negative effects of thermo-mechanical warpage of that semiconductor die.

As described above, thermo-mechanical warpage of a semiconductor die results from a mismatch of the CTEs of the components thereof. The thermal cycling that occurs during normal use of the semiconductor die causes the components thereof to expand and contract, but at different rates due to their differing CTEs. At smaller sizes this warping is less noticeable and has a less-pronounced impact on the effectiveness of thermal management systems designed to cool the semiconductor die. However, with increases in integrated circuit power density and resulting increases in the size of semiconductor dies—driven by processing needs associated with the development and use of artificial intelligence systems—the effects of thermo-mechanical warpage are not only more pronounced, but lead to significant challenges from a thermal management standpoint. One such challenge is that the thermo-mechanical warpage of the semiconductor die results in a thickening—or even separation—of the thermal interface material that facilitates heat transfer between the semiconductor die and the cooling system (in the present example, the pedestal 128). This, in turn, results in lower and less uniform heat transfer, increasing the thermal stress on the semiconductor die and reducing its performance.

The pressure surface 122 of the second geometry 120 mitigates these negative effects by applying pressure to the semiconductor die in a way that counteracts the thermo-mechanical warpage thereof and helps to maintain a uniform thickness of the TIM between the pedestal 128 and the semiconductor die mounted thereto.

The contact surface 118 may be a flat surface or a convex surface. Similarly, the pressure surface 122 may be a flat surface or a convex surface. The pressure surface 122 is raised above the contact surface 118, and may be parallel to the contact surface 118. The contact surface 118 may have a square perimeter, a rectangular perimeter, a circular perimeter, or an elliptical perimeter. Similarly, the pressure surface 122 may have a circular perimeter, an elliptical perimeter, a rectangular perimeter, or a square perimeter. Embodiments of the present disclosure encompass both a contact surface 118 and a pressure surface 122 having any geometric shape. Additionally, the shapes of the contact surface 118 and the pressure surface 122 may be similar or dissimilar.

The pressure surface 122 is significantly smaller than the contact surface 118. For example, the pressure surface 122 may have a total area that is less than five percent of the total area of the contact surface 118, or that is less than three percent of the total area of the contact surface 118. In some embodiments, the total area of the pressure surface 122 may be between two and fifteen percent, and possibly between two and three percent of the total area of the contact surface 118. In some embodiments, the total area of the pressure surface 122 may be between two and 2.5 percent of the total area of the contact surface 118, or between 2.1 and 2.3 percent of the total area of the contact surface 118. For purposes of clarity, the total area of the contact surface does not include the area of the pressure surface.

The pressure surface 122 may be offset from the contact surface 118 by (e.g., may be positioned above the contact surface 118 by a height of) no more than 100 microns, or no more than fifty microns, or no more than thirty microns, or no more than twenty microns.

The first geometry 116 may be, for example, a right prism, a cylinder, or a plate. The second geometry 120 may also be, for example, a right prism, a cylinder, or a plate. The first geometry 116 may be similar or dissimilar to the second geometry 120.

The second geometry 120 extends from the first geometry 116. The first geometry 116 and the second geometry 120 may be integrally formed from a single piece of material (e.g., by milling a plate so as to obtain a pressure surface 122 offset from a contact surface 118), or the first geometry 116 and the second geometry 120 may be formed separately and subsequently joined together. The first geometry 116 and the second geometry 120 may be formed from copper, silver, diamond, graphite, boron nitride, and/or any other thermally conductive material. In some embodiments, the first geometry 116 may be formed of a first material, and the second geometry 120 may be formed of a second material different than the first material. In other embodiments, the first geometry 116 and the second geometry 120 may be formed of the same material.

As shown in FIGS. 1-2 and 4A, for example, the second geometry 120 may be centrally located relative to the first geometry 116, such that the pressure surface 118 comprises a midpoint that is equidistant from opposite points on the perimeter of the contact surface 122.

Although depicted for use in the cooling system 100, the first geometry 116 (with its contact surface 118) and the second geometry 120 (with its pressure surface 122) may be used in other cooling systems having different elements and/or different arrangements of elements than the cooling system 100.

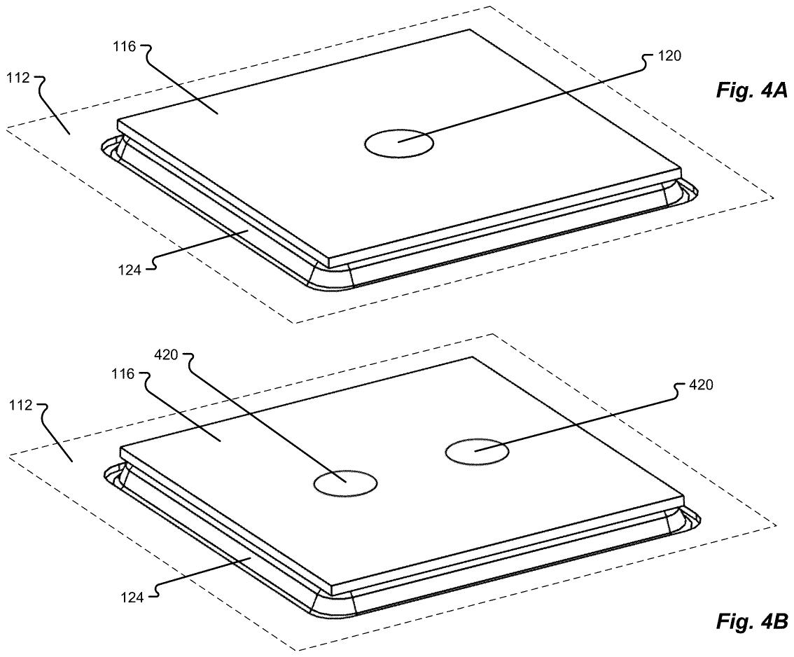

FIG. 4B depicts an alternative variation of the system 100, and more specifically of the pedestal 128, according to at least some embodiments of the present disclosure. In the embodiment of FIG. 4B, the primary portion 112, the raised portion 124, and the contact surface 116 are the same as or substantially similar to those depicted in FIGS. 1-4A. However, the embodiment of FIG. 4B comprises two pressure surfaces 420, equally spaced along an imaginary centerline extending the length of the contact surface 116, midway between the two parallel edges of the contact surface 116. Each of the pressure surfaces 420 may be the same as or similar to the pressure surface 120. The use of a second pressure surface 420 on the contact surface 116 increases thermal performance and yields an improvement in thermal impact of approximately two degrees Celsius over embodiments using a single pressure surface 120.

Embodiments of the present disclosure may utilize one, two, three, four, five, six, or more pressure surfaces such as the pressure surfaces 120 and 420. In embodiments with more than one pressure surface, the multiple pressure surfaces may be arranged, for example, in the same way as the dots on a standard six-sided die, or in a way that achieves approximately equal spacing between the pressure surfaces and the sides of the contact surface 116, or otherwise.

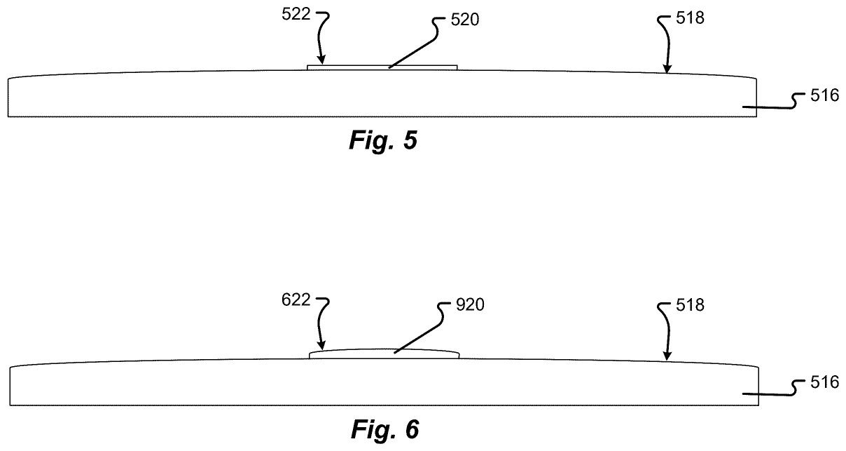

Turning now to FIG. 5, a plate 516 for use in a cooling system (such as the cooling system 100) may be the same as or similar to the first geometry 116 described previously. The plate 516 comprises a convex contact surface 518. In other embodiments, the contact surface 518 may be flat. A protrusion 520, which may be the same as or similar to the second geometry 120, extends from the plate 516 above the contact surface 518, and comprises a pressure surface 522. The pressure surface 522 is flat.

The plate 516 is also shown in FIG. 6. However, the protrusion 620 of FIG. 6—which, like the protrusion 520 of FIG. 5, extends from the plate 516 above the contact surface 518—comprises a convex pressure surface 622.

Notably, the plate 516 and the protrusions 520/620 are not shown to scale in FIGS. 5-6. Possible dimensions of a plate or first geometry such as the plate 516 and first geometry 116, as well as of a protrusion or second geometry such as the protrusions 520 and 620 and second geometry 120, are described in connection with FIG. 8.

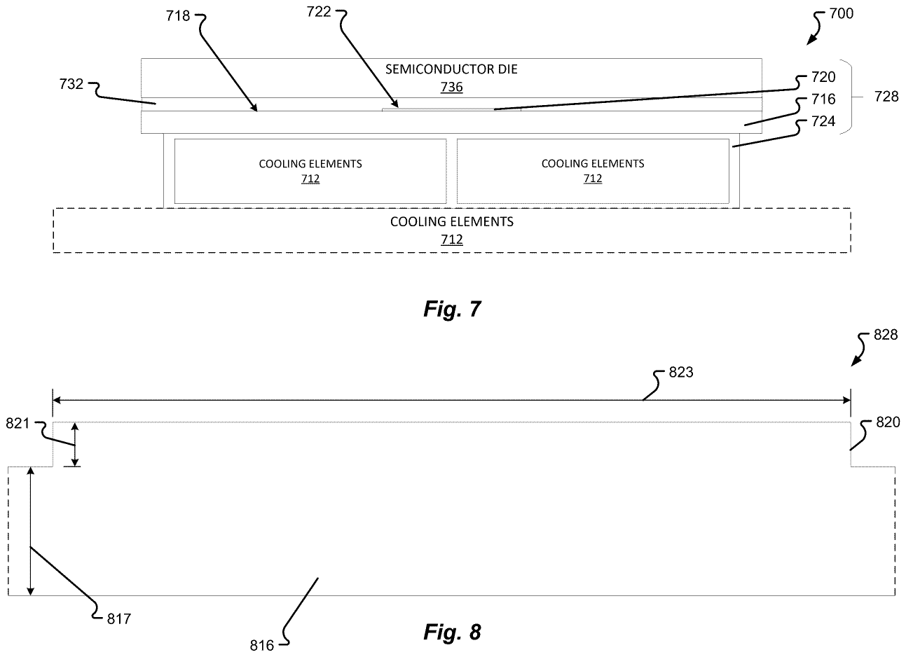

FIG. 7 depicts a block diagram of a cooling system 700 comprising a semiconductor die 736 mounted to a dual-geometry cooling plate according to embodiments of the present disclosure. The system 700 comprises a plurality of cooling elements 712, which may be or comprise heat transfer fluid reservoirs, heat transfer fluid conduits, heat exchangers, fans, pumps, and so forth. A pedestal 728 (which may be the same as or similar to the pedestal 128 described above in connection with FIG. 1) comprises a raised portion 724, a first portion 716, and a second portion 720. The raised portion 724 both comprises one or more cooling elements 712 and is operatively connected to one or more additional cooling elements 712. As just one example, the raised portion 724 may comprise a plurality of heat transfer fluid conduits passing through a heat exchanger configured to transfer heat from an upper surface of the raised portion 724 to a heat transfer fluid. Additionally, the raised portion 724 may be mounted to the housing of a heat transfer fluid reservoir, so that heat transfer fluid is circulated from the heat transfer fluid reservoir, through the cooling elements in the raised portion 724, and then back into the heat transfer fluid reservoir. Other embodiments of the present disclosure utilize other arrangements, however, including different arrangements of the same components and arrangements that utilize more or fewer components and/or one or more different components.

The first portion 716 (which may be the same as or similar to the first geometry 116 described above in connection with FIG. 1) is mounted to and in thermal communication with the raised portion 724. The second portion 720 extends upward from the first portion 716, and together the first portion 716 and the second portion 720 form a dual-geometry cooling plate.

The first portion 716 defines a first geometry and has a contact surface 718, and the second portion 720 defines a second geometry and has a pressure surface 722. The pressure surface 722 is offset from the contact surface 718. The dual-geometry cooling plate inclusive of a pedestal 728 is integrally formed. For example, a copper plate may be milled to define the contact surface 718, the second portion 720, and the pressure surface 722. Any other suitable manufacturing process may also be used to form the first portion 716 and the second portion 720.

The first portion 716 may be the same as or similar to the first geometry 116 and/or the plate 516, and the second portion 720 may be the same as or similar to the second geometry 120 and/or the protrusion 520. As with the contact surfaces 118 and 518 as well as the pressure surfaces 122, 522, and 622, the contact surface 718, as well as the pressure surface 722, may be flat or convex.

The first portion 716 may have a first geometry that is a square or rectangular plate, with a thickness or height of no more than 2000 microns. The second portion 720 may have a second geometry that is a cylinder, with a thickness or height of no more than 50 microns. In some embodiments the first geometry of the first portion 716 matches the second geometry of the second portion 720, while in other embodiments, the two geometries are different.

As discussed elsewhere, the semiconductor die 736 may be any GPU, CPU, QPU, PPU, ASIC, or other processing unit. The semiconductor die may comprise components having different CTEs, and repeated thermal cycling of the semiconductor die may induce thermo-mechanical warping of the semiconductor die 736.

A thermal interface material 732 ensures adequate thermal contact between the dual-geometry cooling plate 728 and the semiconductor die 726. Moreover, the pressure applied to the semiconductor die 736 through the pressure surface 722 of the second portion 720 of the pedestal 728 counteracts the negative effect of warpage of the semiconductor die 736 on the thermal interface material 732 (such as, for example, thickening of the thermal interface material 732), thus helping to ensure that the thermal interface material 732 both maintains a substantially uniform thickness between the pedestal 728 and the semiconductor die 736, and does not separate from either of those components.

FIG. 8 depicts a partial illustration of a dual-geometry cooling plate 828 comprising a first geometry 816 (which may be the same as or similar to the first geometry 116, the plate 516, and/or the first portion 716) and a second geometry 820 (which may be the same as or similar to the second geometry 120, the protrusions 520 or 620, and/or the second portion 720). The features of FIG. 8 are not drawn to scale, but rather are shown with exaggerated proportions to facilitate a description of the dimensions thereof.

More specifically, the first geometry 816 has a height or thickness 817 of no more than 2000 microns. The height or thickness 817 may be between 1000 and 2000 microns, or between 1200 and 1800 microns, or between 1400 and 1700 microns. The second geometry 820 has a height or thickness 821 of no more than 100 microns. The height or thickness 821 may be no more than 50 microns, or no more than 35 microns, or more than 25 microns, or between 25 and 35 microns. The second geometry 820 has a diameter 823 of less than 50 mm, or less than 40 mm, or less than 30 mm, or less than 20 mm, or between 5 and 20 mm, or between 5 and 15 mm.

In describing embodiments of the present disclosure, the second geometry 120, protrusions 520 and 620, second portion 720, and second geometry 820 may alternatively be referred to as a coin, bump, or disc.

Any of the embodiments described herein in connection with FIGS. 1-8 may comprise one or more features or characteristics described in connection with any other one or more of those embodiments.

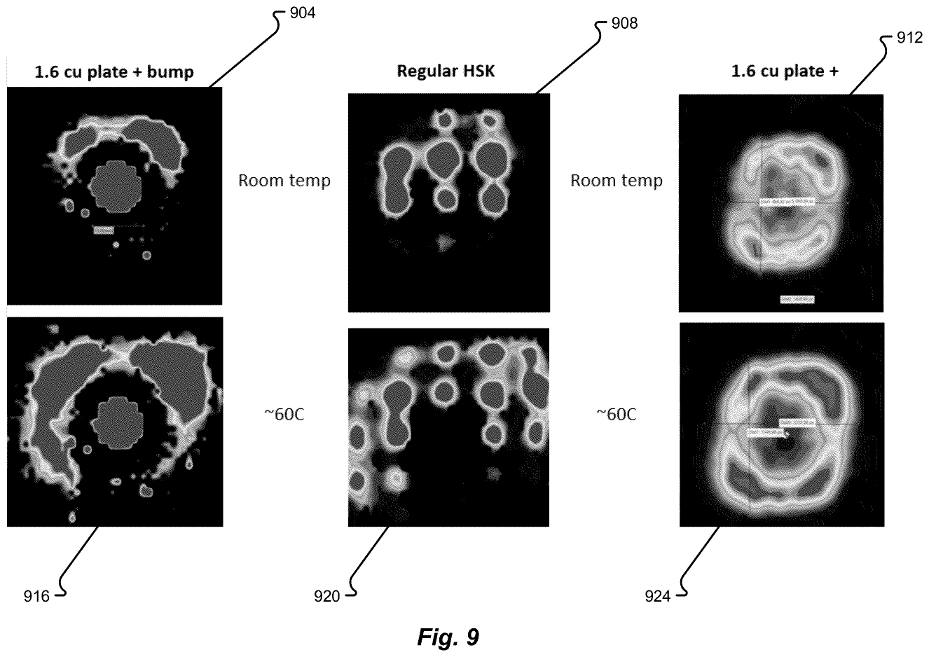

FIG. 9 comprises thermal images showing the significant improvement in heat transfer achieved when using a dual-geometry cooling plate to cool a semiconductor die according to embodiments of the present disclosure. More specifically, image 904 shows the heat transfer achieved at room temperature using a dual-geometry cooling plate according to embodiments of the present disclosure, while images 908 and 912 show the heat transfer achieved at room temperature without using a dual-geometry cooling plate according to embodiments of the present disclosure.

Similarly, image 916 shows the heat transfer achieved at approximately 60 degrees Celsius using a dual-geometry cooling plate according to embodiments of the present disclosure, while images 920 and 924 show the heat transfer achieved at the same temperature without using a dual-geometry cooling plate according to embodiments of the present disclosure. As can be seen, the improvement in heat transfer using embodiments of the present disclosure is especially pronounced at higher temperatures, where effective thermal management is especially critical to ensure optimal performance of the cooled semiconductor die.

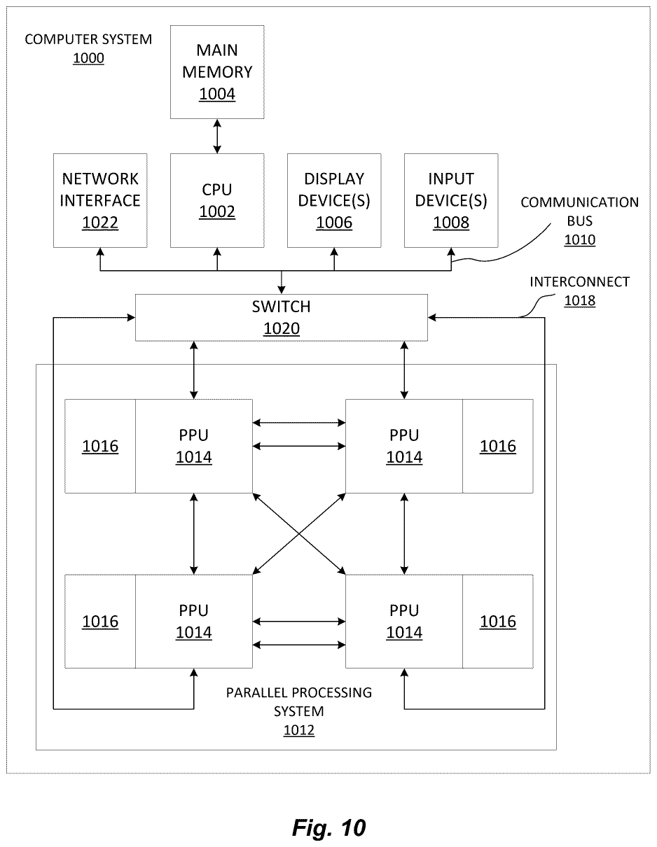

FIG. 10 illustrates a computer system 1000, according to at least one embodiment. In at least one embodiment, the systems and devices described throughout this disclosure may be implemented in connection with a computer system 1000.

In at least one embodiment, computer system 1000 comprises, without limitation, at least one central processing unit (“CPU”) 1002 that is connected to a communication bus 1010 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1000 includes, without limitation, a main memory 1004. Control logic (e.g., implemented as hardware, software, or a combination thereof) and data are stored in main memory 1004 which may take form of random access memory (“RAM”). In at least one embodiment, a network interface subsystem (“network interface”) 1022 provides an interface to other computing devices and networks for receiving data from and transmitting data to other systems from computer system 1000.

In at least one embodiment, computer system 1000, includes, without limitation, input devices 1008, parallel processing system 1012, and display devices 1006 which can be implemented using a conventional cathode ray tube (“CRT”), liquid crystal display (“LCD”), light emitting diode (“LED”), plasma display, or other suitable display technologies. In at least one embodiment, user input is received from input devices 1008 such as keyboard, mouse, touchpad, microphone, and more. In at least one embodiment, each of the foregoing modules can be situated on a single semiconductor platform to form a processing system.

In at least one embodiment, computer programs in the form of machine-readable executable code or computer control logic algorithms are stored in main memory 1004 and/or secondary storage. Computer programs, if executed by one or more processors, enable system 1000 to perform various functions in accordance with at least one embodiment. Memory 1004, secondary storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, the architecture and/or functionality of various figures described herein is/are implemented in the context of CPU 1002; parallel processing system 1012; an integrated circuit capable of at least a portion of capabilities of both CPU 1002 and parallel processing system 1012; a chipset (e.g., a group of integrated circuits designed to work and sold as a unit for performing related functions, etc.); and any suitable combination of integrated circuit(s).

In at least one embodiment, the architecture and/or functionality of various figures described herein is/are implemented in the context of a general computer system, a circuit board system, a game console system dedicated for entertainment purposes, an application-specific system, and more. In at least one embodiment, computer system 1000 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1012 includes, without limitation, a plurality of parallel processing units (“PPUs”) 1016 and associated memories 1016. In at least one embodiment, PPUs 1016 are connected to a host processor or other peripheral devices via an interconnect 1018 and a switch 1020 or multiplexer. In at least one embodiment, parallel processing system 1012 distributes computational tasks across PPUs 1016 which can be parallelizable—for example, as part of a distribution of computational tasks across multiple graphics processing unit (“GPU”) thread blocks. In at least one embodiment, memory is shared and accessible (e.g., for read and/or write access) across some or all of PPUs 1016, although such shared memory may incur performance penalties relative to the use of local memory and registers resident to a PPU 1016. In at least one embodiment, operation of PPUs 1016 is synchronized through use of a command such as syncthreads( ), which requires all threads in a block (e.g., executed across multiple PPUs 1016) to reach a certain point of execution of code before proceeding.

Each of the CPU 1002 and the PPUs 1014 illustrated in FIG. 10 may be cooled, for example, using embodiments of the present disclosure.

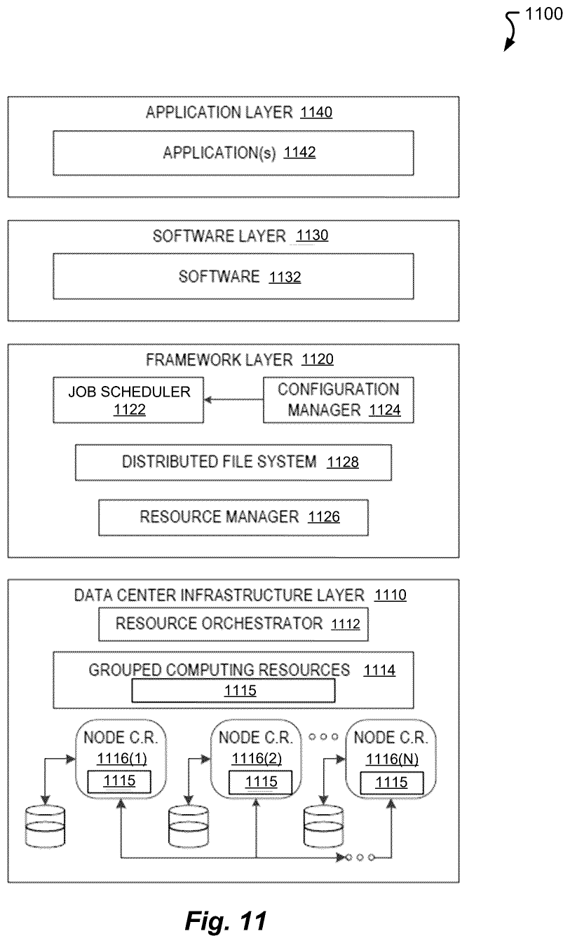

FIG. 11 illustrates additional components of an example datacenter 1100 according to at least some embodiments of the present disclosure. The datacenter 1100 may also include one or more modules subject to one or more cooling/thermal management features as described herein.

In at least one embodiment, datacenter 1100 includes a datacenter infrastructure layer 1110, a framework layer 1120, a software layer 1130, and an application layer 1140. In at least one embodiment, the infrastructure layer 1110, the framework layer 1120, the software layer 1130, and the application layer 1140 may be partly or fully provided via computing components on server trays located in racks of the datacenter 1100 (or of another datacenter) . This enables cooling systems of the present disclosure to direct cooling to certain ones of the computing features and the interconnect features, in an efficient and effective manner. Further, aspects of the datacenter 1100, including the datacenter infrastructure layer 1110, the framework layer 1120, the software layer 1130, and the application layer 1140 may be used to support selection or design of the intermediate layers. As such, the discussion in reference to FIG. 11 may be understood to apply to the hardware and software features required to enable or support cooling functionality, for instance.

In at least one embodiment, as in FIG. 11, datacenter infrastructure layer 1110 may include a resource orchestrator 1112, grouped computing resources 1114, and node computing resources (“node C.R.s”) 1116(1)-1116(N), where “N” represents any whole, positive integer. In at least one embodiment, node C.R.s 1116(1)-1116(N) may include, but are not limited to, any number of central processing units (“CPUs”) or other processors (including accelerators, field programmable gate arrays (FPGAs), graphics processors, etc.), memory devices (such as dynamic read-only memory), storage devices (such as solid state or disk drives), network input/output (“NW I/O”) devices, network switches, virtual machines (“VMs”), power modules, and cooling modules, etc. In at least one embodiment, one or more node C.R.s from among node C.R.s 1116(1)-1116(N) may be a server having one or more of above-mentioned computing resources.

In at least one embodiment, grouped computing resources 1114 may include separate groupings of node C.R.s housed within one or more racks (not shown), or many racks housed in datacenters at various geographical locations (also not shown). Separate groupings of node C.R.s within grouped computing resources 1114 may include grouped compute, network, memory or storage resources that may be configured or allocated to support one or more workloads. In at least one embodiment, several node C.R.s including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 1112 may configure or otherwise control one or more node C.R.s 1116(1)-1116(N) and/or grouped computing resources 1114. In at least one embodiment, resource orchestrator 1112 may include a software design infrastructure (“SDI”) management entity for datacenter 1100. In at least one embodiment, resource orchestrator may include hardware, software or some combination thereof.

In at least one embodiment, as shown in FIG. 11, framework layer 1120 includes a job scheduler 1122, a configuration manager 1124, a resource manager 1126 and a distributed file system 1128. In at least one embodiment, framework layer 1120 may include a framework to support software 1132 of software layer 1130 and/or one or more application(s) 1142 of application layer 1140. In at least one embodiment, software 1132 or application(s) 1142 may respectively include web-based service software or applications, such as those provided by Amazon Web Services, Google Cloud and Microsoft Azure. In at least one embodiment, framework layer 1120 may be, but is not limited to, a type of free and open-source software web application framework such as Apache Spark™ (hereinafter “Spark”) that may utilize distributed file system 1128 for large-scale data processing (such as “big data”). In at least one embodiment, job scheduler 1122 may include a Spark driver to facilitate scheduling of workloads supported by various layers of datacenter 1100. In at least one embodiment, configuration manager 1124 may be capable of configuring different layers such as software layer 1130 and framework layer 1120 including Spark and distributed file system 1128 for supporting large-scale data processing. In at least one embodiment, resource manager 1126 may be capable of managing clustered or grouped computing resources mapped to or allocated for support of distributed file system 1128 and job scheduler 1122. In at least one embodiment, clustered or grouped computing resources may include grouped computing resource 1114 at datacenter infrastructure layer 1110. In at least one embodiment, resource manager 1126 may coordinate with resource orchestrator 1112 to manage these mapped or allocated computing resources.

In at least one embodiment, software 1132 included in software layer 1130 may include software used by at least portions of node C.R.s 1116(1)-1116(N), grouped computing resources 1114, and/or distributed file system 1128 of framework layer 1120. One or more types of software may include, but are not limited to, Internet web page search software, e-mail virus scan software, database software, and streaming video content software.

In at least one embodiment, application(s) 1142 included in application layer 1140 may include one or more types of applications used by at least portions of node C.R.s 1116(1)-1116(N), grouped computing resources 1114, and/or distributed file system 1128 of framework layer 1120. One or more types of applications may include, but are not limited to, any number of a genomics application, a cognitive compute, and a machine learning application, including training or inferencing software, machine learning framework software (such as PyTorch, TensorFlow, Caffe, etc.) or other machine learning applications used in conjunction with one or more embodiments.

In at least one embodiment, any of configuration manager 1124, resource manager 1126, and resource orchestrator 1112 may implement any number and type of self-modifying actions based on any amount and type of data acquired in any technically feasible fashion. In at least one embodiment, self-modifying actions may relieve a datacenter operator of datacenter 1100 from making possibly bad configuration decisions and possibly avoiding underutilized and/or poor performing portions of a datacenter.

In at least one embodiment, datacenter 1100 may include tools, services, software or other resources to train one or more machine learning models or predict or infer information using one or more machine learning models according to one or more embodiments described herein. In at least one embodiment, a machine learning model may be trained by calculating weight parameters according to a neural network architecture using software and computing resources described above with respect to datacenter 1100. In at least one embodiment, trained machine learning models corresponding to one or more neural networks may be used to infer or predict information using resources described above with respect to datacenter 1100 by using weight parameters calculated through one or more training techniques. Deep learning may be advanced using any appropriate learning network and the computing capabilities of the datacenter 1100. As such, a deep neural network (DNN), a recurrent neural network (RNN) or a convolutional neural network (CNN) may be supported either simultaneously or concurrently using the hardware in the datacenter. Once a network is trained and successfully evaluated to recognize data within a subset or a slice, for instance, the trained network can provide similar representative data for using with the collected data.

In at least one embodiment, datacenter 1100 may use CPUs, application-specific integrated circuits (ASICs), GPUs, FPGAs, or other hardware to perform training and/or inferencing using above-described resources. Such hardware may be cooled, for example, using embodiments of the present disclosure. Moreover, one or more software and/or hardware resources described above may be configured as a service to allow users to train or perform inferencing of information, such as pressure, flow rates, temperature, and location information, or as any other artificial intelligence service.

Inference and/or training logic 1115 may be used to perform inferencing and/or training operations associated with one or more embodiments. In at least one embodiment, inference and/or training logic 1115 may be used in a datacenter 1100 (whether in grouped computing resources 1114, in one or more node C.R.s 1116(1)-1116(N), or elsewhere) or in other systems described herein, for inferencing or predicting operations based, at least in part, on weight parameters calculated using neural network training operations, neural network functions and/or architectures, or neural network use cases described herein. In at least one embodiment, inference and/or training logic 1115 may include, without limitation, hardware logic in which computational resources are dedicated or otherwise exclusively used in conjunction with weight values or other information corresponding to one or more layers of neurons within a neural network. In at least one embodiment, inference and/or training logic 1115 may be used in conjunction with an application-specific integrated circuit (ASIC), such as a Tensorflow® Processing Unit from Google, an inference processing unit (IPU) from Graphcore™, or a Nervana® (such as “Lake Crest”) processor from Intel Corp. Such hardware may be cooled, for example, using embodiments of the present disclosure.

In at least one embodiment, inference and/or training logic 1115 may be used in conjunction with central processing unit (CPU) hardware, graphics processing unit (GPU) hardware or other hardware, such as field programmable gate arrays (FPGAs)—each of which may be cooled, for example, using embodiments of the present disclosure. In at least one embodiment, inference and/or training logic 1115 includes, without limitation, code and/or data storage modules which may be used to store code (such as graph code), weight values and/or other information, including bias values, gradient information, momentum values, and/or other parameter or hyperparameter information. In at least one embodiment, each of the code and/or data storage modules is associated with a dedicated computational resource. In at least one embodiment, the dedicated computational resource includes computational hardware that further include one or more ALUs that perform mathematical functions, such as linear algebraic functions, only on information stored in code and/or data storage modules, and results from which are stored in an activation storage module of the inference and/or training logic 1115.

The switches within each layer (e.g., edge layer, aggregation layer, core layer) may be 1U switches. The switches may be electrical switches, optical switches, hybrid electro-optical switches, or any combination thereof. The switches may be implemented with suitable hardware and/or software that enables the routing of signals in the appropriate domain. For example, an electrical switch may include receivers that receive and convert optical signals into electrical signals for routing within the electrical switch. A receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In some embodiments, receiver/transmitter pairs may be integrated into a single transceiver. Each electrical switch may also include internal switching circuitry for routing electrical signals within the electrical switch.

A switch, whether electric, optoelectronic, and/or quantum, may include input circuit(s) and output circuit(s), linked by switching core. In some embodiments, a switch may include multiple inputs and outputs.

A number of architectures of this type have been proposed, including “Next Generation I/O” (NGIO) and “Future I/O” (FIO), culminating in the “InfiniBand” architecture, which has been advanced by a consortium led by a group of industry leaders (including Intel, Sun, Hewlett Packard, IBM, Compaq, Dell and Microsoft). Storage Area Networks (SAN) provide a similar, packetized, serial approach to high-speed storage access, which can also be implemented using an InfiniBand fabric.

Communications between a parallel bus and a packet network generally require a communications interface, to convert bus cycles into appropriate packets and vice versa. For example, a host channel adapter or target channel adapter can be used to link a parallel bus, such as the PCI bus, to the InfiniBand fabric. When the adapter receives data from a device on the PCI bus, it inserts the data in the payload of an InfiniBand packet, and then adds an appropriate header and error checking code, such as a cyclic redundancy check (CRC) code, as required for network transmission. The InfiniBand packet header includes a routing header and a transport header. The routing header contains information at the data link protocol level, including fields required for routing the packet within and between fabric subnets. The transport header contains higher-level, end-to-end transport protocol information. Similar headers are used in other types of packet networks known in the art, such as Internet Protocol (IP) networks.

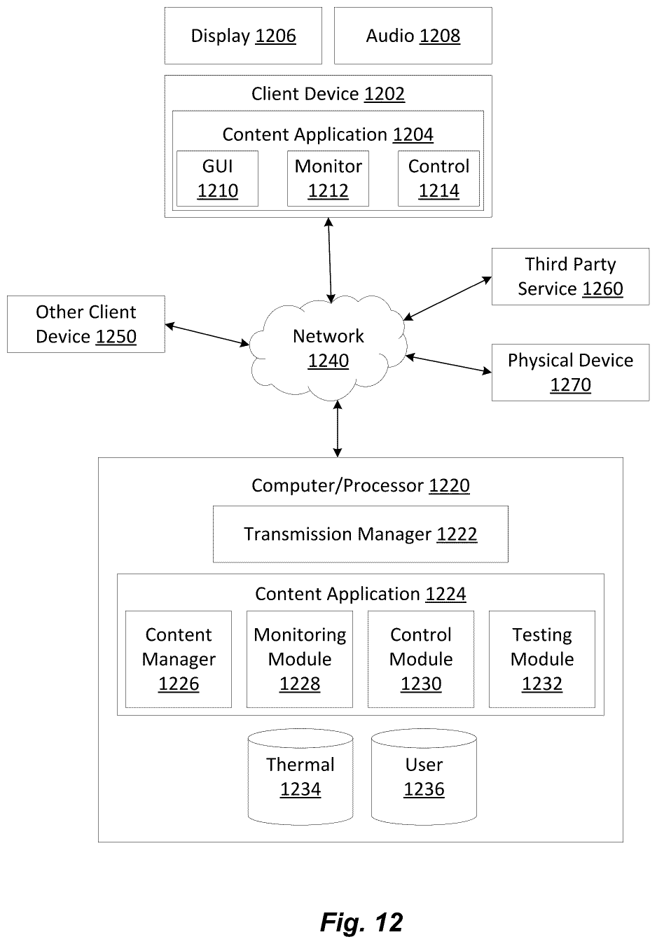

FIG. 12 illustrates an example network configuration 1200 of components that can be used to implement aspects of various embodiments, such as to provide, generate, modify, encode, process, fuse, and/or transmit generated image data, calculated measurements, or other such content. In at least one embodiment, a client device 1202 can generate or receive data for a session using components of a content application 1204 on the client device 1202 and data stored locally on that client device. In at least one embodiment, a content application 1224 executing on a computer or processor 1220 (e.g., a cloud server or control system) may initiate a session associated with at least one client device 1202 (e.g., a vehicle or robot), as may use a session manager and user data stored in a user database 1236, and can cause content such as liquid coolant or server thermal data to be selected and/or retrieved from a repository 1234 to be used by a testing module 1232 to calculate one or more performance metrics for a monitoring module 1228, which can provide flow data or thermal data to a control module 1230 to control a flow or temperature, in an environment where the data is to be used to determine appropriate operation.

A content manager 1226 may work with at these various modules to perform testing and analysis, and potentially instruct any actions to be taken in response to a performance metric failing to satisfy an operational requirements. At least a portion of this data or instructional content can be transmitted to the client device 1202 and/or a physical device 1270 using an appropriate transmission manager 1222 to send by download, streaming, or another such transmission channel. An encoder may be used to encode and/or compress at least some of this data before transmitting to the client device 1202. In at least one embodiment, the client device 1202 receiving such content can provide this content to a corresponding content application 1204, which may also or alternatively include a graphical user interface 1210, a flow monitor module 1212, and a control module 1214 for use in providing, synthesizing, rendering, compositing, modifying, or using content for presentation, navigation, control, (or other purposes) on or by the client device 1202, such as may be transmitted to the physical device 1270.

In some embodiments, the computer/processor 1220 and client device 1202 may be able to communicate directly without needing to transmit data over a network 1240, in order to avoid issues with latency and availability, etc. A decoder may also be used to decode data received over the network 1240 for presentation via client device 1202, such as imaging content or performance metrics through a display device 1206 and audio, such as corresponding sounds or synthesized speech, through at least one audio playback device 1208, such as speakers or headphones.

In at least one embodiment, at least some of this content may already be stored on, rendered on, or accessible to client device 1202 such that transmission over a network 1240 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer/processor 1220, or user database 1236, to the client device 1202. In at least one embodiment, at least a portion of this content can be obtained, enhanced, and/or streamed from another source, such as a third party service 1260 or other client device 1250, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit).

In at least some of these examples, client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options.

In this example, these requests can be submitted to an address associated with a cloud provider, who may operate or control one or more electronic resources in a cloud provider environment, such as may include a data center or server farm. In at least one embodiment, the request may be received or processed by at least one edge server, that sits on a network edge and is outside at least one security layer associated with the cloud provider environment. In this way, latency can be reduced by allowing the client devices to interact with servers that are in closer proximity, while also improving security of resources in the cloud provider environment.

In at least one embodiment, such a system can be used for monitoring or managing thermal conditions of a server which includes cold plates as liquid manifolds. In other embodiments, such a system can be used for other purposes, such as for providing control of liquid coolant flow, or for performing deep learning operations. In at least one embodiment, such a system can be implemented using an edge device or may incorporate one or more Virtual Machines (VMs). In at least one embodiment, such a system can be implemented at least partially in a data center or at least partially using cloud computing resources.

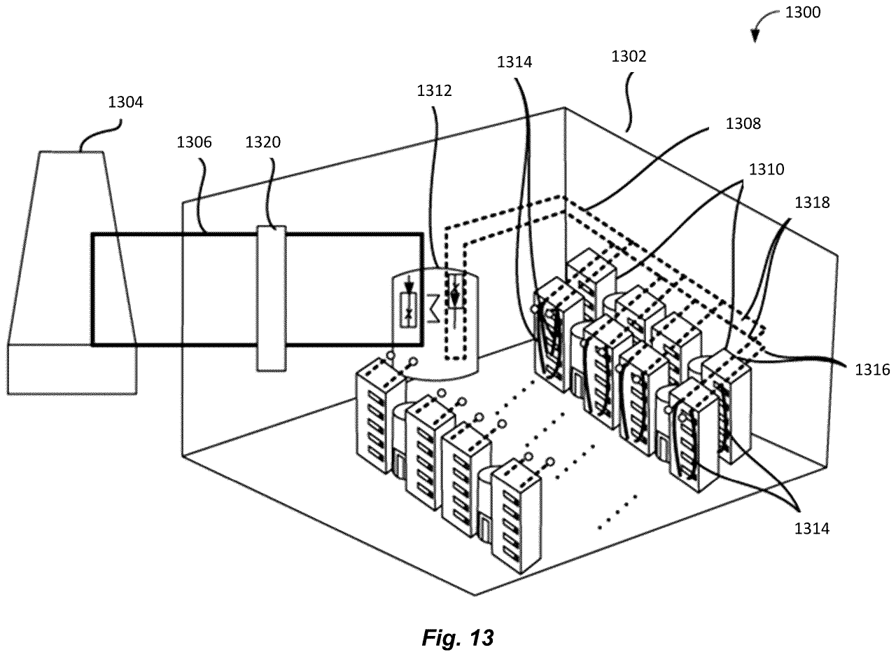

According to at least some embodiments of the present disclosure, an exemplary datacenter 1300 can be utilized as illustrated in FIG. 13, which has a cooling system subject to improvements described herein. Any one or more of the features described below may be included in the system 100 described above, and/or in any other cooling system or portion thereof (including any pedestal) described herein.

In at least one embodiment, numerous specific details are set forth to provide a thorough understanding, but concepts herein may be practiced without one or more of these specific details. In at least one embodiment, datacenter cooling systems can respond to sudden high heat requirements caused by changing computing-loads in present day computing components. In at least one embodiment, as these requirements are subject to change or tend to range from a minimum to a maximum of different cooling requirements, these requirements must be met in an economical manner, using an appropriate cooling system. In at least one embodiment, for moderate to high cooling requirements, liquid cooling system may be used. In at least one embodiment, high cooling requirements are economically satisfied by localized immersion cooling. In at least one embodiment, these different cooling requirements also reflect different heat features of a datacenter. In at least one embodiment, heat generated from these components, servers, and racks are cumulatively referred to as a heat feature or a cooling requirement as cooling requirement must address a heat feature entirely.

In at least one embodiment, a datacenter liquid cooling system is disclosed. In at least one embodiment, this datacenter cooling system addresses heat features in associated computing or datacenter devices, such as in graphics processing units (GPUs), in switches, in dual inline memory module (DIMMs), or central processing units (CPUs). In at least one embodiment, these components may be referred to herein as high heat density computing components. Furthermore, in at least one embodiment, an associated computing or datacenter device may be a processing card having one or more GPUs, switches, or CPUs thereon. In at least one embodiment, each of GPUs, switches, and CPUs may be a heat generating feature of a computing device. In at least one embodiment, a GPU, a CPU, or a switch may have one or more cores, and each core may be a heat generating feature.

In at least one embodiment, a cold plate includes adjustable fins forming microchannels for fluid to flow through. In at least one embodiment, fins in a cold plate enable transfer of heat from at least one associated computing device to a fluid flowing through microchannels formed between multiple fins. In at least one embodiment, fins of a cold plate are dynamically and adjustable in real time to allow transfer of more heat from at least one computing device to a fluid that flows through a cold plate having fins. In at least one embodiment, such fins may be adjusted by a processor or processorless system based in part on a temperature determined, such as sensed, for a cold plate. In at least one embodiment, a temperature may be associated with at least one computing device, a workload of at least one computing device, or a fluid at different time periods and at an entry, and at an egress of a cold plate. In at least one embodiment, a processorless system may rely on a thermal property of at least two materials used to form fins for a cold plate so that such fins may react without a processor to cause exposure of more surface area to a fluid. In at least one embodiment, such fins may include an overlapping portion that may be caused to be exposed by action of a control mechanism or by properties of at least two materials associated together to form a fin.

In at least one embodiment, a cold plate has a top plate, a bottom plate, and fins in between. In at least one embodiment, a bottom plate may be a base of a cold plate. In at least one embodiment, a top plate may be intermediary between a cover plate of a cold plate and a bottom or base plate of a cold plate. In at least one embodiment, fins may be coupled to a bottom or base plate and to a top plate so that a top plate may be moved to uncover an overlapping portion of each fin and expose an overlapping portion of each fin to fluid flowing through a cold plate. In at least one embodiment, exposure of an overlapping portion of each fin results in surface area previously covered to be exposed to fluid and to provide additional cooling of fins of a cold plate, and by association, of an associated computing device.

In at least one embodiment, multiple fins form microchannels for fluid to flow therebetween. In at least one embodiment, such fins are able to actively or passively react to thermal feedback by a modification of microchannels to enable fluid to absorb more heat from at least one computing device. In at least one embodiment, an active reaction may be enabled by at least one processor that can expose more surface area of such fins by expanding an overlapping portion of such fins. In at least one embodiment, a passive reaction may be enabled by a thermal property of materials associated together to form each fin of such fins that allows such fins to expand.

In at least one embodiment, issues of cold plates being static devices are addressed by intelligent and dynamic cold plates herein. In at least one embodiment, an intelligent and dynamic cold plate allows a cold plate (via its internal features) to react to sensed or determined temperature from at least one computing device. In at least one embodiment, compared to static cold plates, intelligence aspects of an intelligent and dynamic cold plate allow sensor inputs to be used to modify provided fins of such a cold plate. In at least one embodiment, microchannels formed by such fins are able to be changed to cause a change in a fluid path or to increase interaction surfaces between a fluid and each such fin. In at least one embodiment, such aspects allow more fluid to pass through to certain areas or to pass through certain areas and allow heat removal in those areas where high heat density occurs from at least one computing device.

In at least one embodiment, static cold plates used for liquid cooling of GPU, CPU, Switches, and other high heat density components may have static microchannels allowing flow of fluid therein to remove heat from such heat dissipating components in datacenters. In at least one embodiment, static cold plates incorporate design and methods for heat removal that are not related to or reactive to heat density or heat dissipation by computing components. In at least one embodiment, some cold plates may have varying thermal behaviors depending on computational, environmental and other attributes that require a dynamic behavior for achieving optimum heat removal capability for available resources in a liquid cooled environment.

In at least one embodiment, an indirect cooling cold plate, which is liquid-cooled, may be composed of parts therein. In at least one embodiment, two parts may be provided so that a bottom or base layer or part provides a rigid mechanical attachment and also works as a highly thermal conductive medium where heat is conducted from computing components (GPU, Switch, and CPU) to multiple fins forming microchannels over a bottom or base plate or part. In at least one embodiment, such fins are built into a base metal and may be associated with a top or upper plate or part, which is an intermediary plate or part. In at least one embodiment, a top or upper plate or part that is an intermediary plate or part is non-conductive and made of a non-conductive material. In at least one embodiment, a cover plate encloses (with side plates) such parts within an intelligent and dynamic cold plate.

In at least one embodiment, a top or upper plate or part, by its intermediary plate or part function, is able to dynamically modify a base plate's microchannel fluid path based in part on an instantaneous thermal behavior of heating components associated with an intelligent and dynamic cold plate. In at least one embodiment, using intelligent sensing, inferencing and adaptive modification, microchannels forming fluid paths may be dynamically adjusted to cause or rush more fluid (for heat removal) to areas of high heat density within an intelligent and dynamic cold plate. In at least one embodiment, such features also enable simultaneous reduction of fluids flow to block microchannels for areas where there is less demand for heat removal determined or sensed from a base plate of an intelligent and dynamic cold plate. In at least one embodiment, an overlapping portion of provided fins within an intelligent and dynamic cold plate may be used to block or restrict microchannels by being thicker at an overlapping portion between fins of an intelligent and dynamic cold plate. In at least one embodiment, multiple top plates may be provided to function as intermediary plates and may each be associated with different fins. In at least one embodiment, movement of different top plates achieve different blocks or restrictions or flow redirection within an intelligent and dynamic cold plate.

In at least one embodiment, an exemplary datacenter 1300 can be utilized as illustrated in FIG. 13, which has a cooling system subject to improvements described herein. In at least one embodiment, a datacenter 1300 may be one or more rooms 1302 having racks 1310 and auxiliary equipment to house one or more servers on one or more server trays. In at least one embodiment, a datacenter 1300 is supported by a cooling tower 1304 located external to a datacenter 1300. In at least one embodiment, a cooling tower 1304 dissipates heat from within a datacenter 1300 by acting on a primary cooling loop 1306. In at least one embodiment, a cooling distribution unit (CDU) 1312 is used between a primary cooling loop 1306 and a second or secondary cooling loop 1308 to enable absorption of heat from a second or secondary cooling loop 1308 to a primary cooling loop 1306. In at least one embodiment, a secondary cooling loop 1308 can access various plumbing into a server tray as required, in an aspect. In at least one embodiment, loops 1306, 1308 are illustrated as line drawings, but a person of ordinary skill would recognize that one or more plumbing features may be used. In at least one embodiment, flexible polyvinyl chloride (PVC) pipes may be used along with associated plumbing to move fluid along in each provided loop 1306; 1308. In at least one embodiment, one or more coolant pumps may be used to maintain pressure differences within coolant loops 1306, 1308 to enable movement of coolant according to temperature sensors in various locations, including in a room, in one or more racks 1310, and/or in server boxes or server trays within one or more racks 1310.

In at least one embodiment, coolant in a primary cooling loop 1306 and in a secondary cooling loop 1308 may be at least water and an additive. In at least one embodiment, an additive may be glycol or propylene glycol. In operation, in at least one embodiment, each of a primary and a secondary cooling loops may have their own coolant. In at least one embodiment, coolant in secondary cooling loops may be proprietary to requirements of components in a server tray or in associated racks 1310. In at least one embodiment, a CDU 1312 is capable of sophisticated control of coolants, independently or concurrently, within provided coolant loops 1306, 1308. In at least one embodiment, a CDU may be adapted to control flow rate of coolant so that coolant is appropriately distributed to absorbed heat generated within associated racks 1310. In at least one embodiment, more flexible tubing 1314 is provided from a secondary cooling loop 1308 to enter each server tray to provide coolant to electrical and/or computing components therein.

The heat transfer fluid generally includes water, water solutions (e.g. propylene glycol-water), brine, antifreeze, a mixture of antifreeze and water, oil, alcohol, mercury or the like or any other suitable heat conductive fluid. The heat transfer fluid may be an electrically conductive cooling liquid and may include water, deionized water, or a coolant such as R-134a, a mixture of water and additives, such as a mixture of water and ethylene glycol or a mixture of water and propylene glycol e.g. a 25% concentration of propylene glycol in deionized water. The heat transfer fluid may also be a dielectric fluid alone (e.g., not having water for purposes of this disclosure) or a water in combination with an additive including at least one dielectric fluid, such as or one or more of de-ionized water, ethylene glycol, and propylene glycol. In at least one embodiment, the heat transfer fluid may be an absorption chiller having a working fluid being a mixed solution containing lithium bromide as the absorbent material and water as the carrier material. The heat transfer fluid may also be a two-phase coolant that has a boiling point that is below the expected operating temperature of the electronic devices. Exemplary two-phase coolants include 2, 3, 3, 3-tetrafluoropropene, 1, 1, 1, 2-tetrafluoroethane and water.

In at least one embodiment, tubing 1318 that forms part of a secondary cooling loop 1308 may be referred to as room manifolds. Separately, in at least one embodiment, further tubing 1316 may extend from row manifold tubing 1318 and may also be part of a secondary cooling loop 1308 but may be referred to as row manifolds. In at least one embodiment, coolant tubing 1314 enters racks as part of a secondary cooling loop 1308 but may be referred to as rack cooling manifold within one or more racks. In at least one embodiment, row manifolds 1316 extend to all racks along a row in a datacenter 1300. In at least one embodiment, plumbing of a secondary cooling loop 1308, including coolant manifolds 1318, 1316, and 1314 may be improved by at least one embodiment herein. In at least one embodiment, a chiller 1320 may be provided in a primary cooling loop within datacenter 1302 to support cooling before a cooling tower. In at least one embodiment, additional cooling loops that may exist in a primary control loop and that provide cooling external to a rack and external to a secondary cooling loop, may be taken together with a primary cooling loop and is distinct from a secondary cooling loop, for this disclosure.

In at least one embodiment, in operation, heat generated within server trays of provided racks 1310 may be transferred to a coolant exiting one or more racks 1310 via flexible tubing of a row manifold 1314 of a second cooling loop 1308. In at least one embodiment, second coolant (in a secondary cooling loop 1308) from a CDU 1312, for cooling provided racks 1310, moves towards one or more racks 1310 via provided tubing. In at least one embodiment, second coolant from a CDU 1312 passes from on one side of a room manifold having tubing 1318, to one side of a rack 1310 via a row manifold 1316, and through one side of a server tray via different tubing 1314. In at least one embodiment, spent or returned second coolant (or exiting second coolant carrying heat from computing components) exits out of another side of a server tray (such as enter left side of a rack and exits right side of a rack for a server tray after looping through a server tray or through components on a server tray). In at least one embodiment, spent second coolant that exits a server tray or a rack 1310 comes out of different side (such as exiting side) of tubing 1314 and moves to a parallel, but also exiting side of a row manifold 1316. In at least one embodiment, from a row manifold 1316, spent second coolant moves in a parallel portion of a room manifold 1318 and is going in an opposite direction than incoming second coolant (which may also be renewed second coolant), and towards a CDU 1312.

In at least one embodiment, spent second coolant exchanges its heat with a primary coolant in a primary cooling loop 1306 via a CDU 1312. In at least one embodiment, spent second coolant may be renewed (such as relatively cooled when compared to a temperature at a spent second coolant stage) and ready to be cycled back to through a second cooling loop 1308 to one or more computing components. In at least one embodiment, various flow and temperature control features in a CDU 1312 enable control of heat exchanged from spent second coolant or flow of second coolant in and out of a CDU 1312. In at least one embodiment, a CDU 1312 may be also able to control a flow of primary coolant in primary cooling loop 1306.

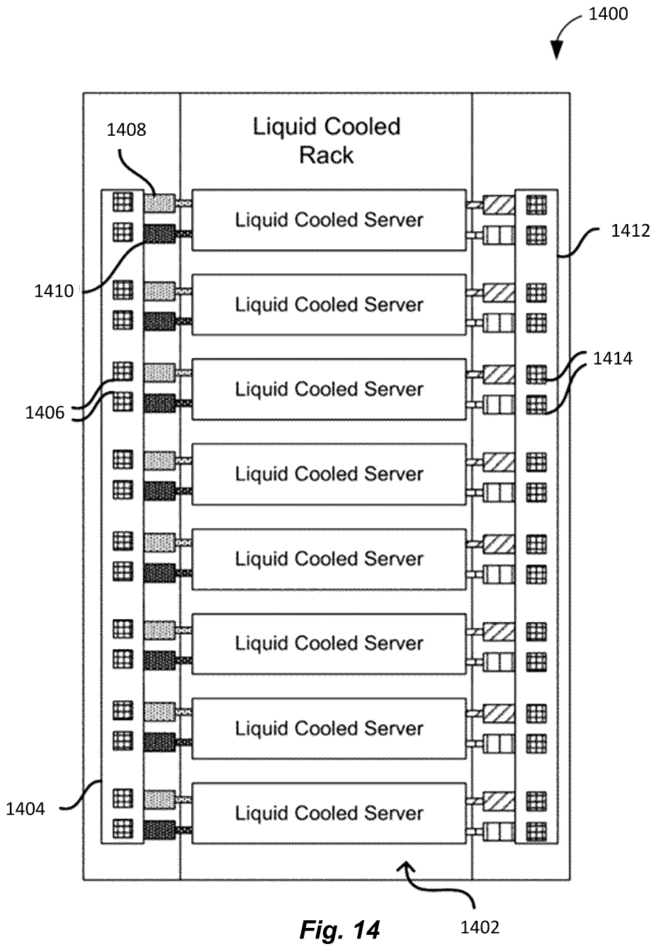

Turning now to FIG. 14, in at least one embodiment, neural networks can be embedded in various devices to enable those devices to predict future state, and make proactive adjustments based at least in part upon those predictions. In at least one embodiment, this can include neural network enabled devices to be installed directly in a liquid cooled server rack 1400. In at least one embodiment, rack 1400 can include a number of liquid cooled servers 1402 or other such devices. In at least one embodiment, a neural network enabled rack manifold 1404 can be included in rack 1400 to provide a flow of liquid into each liquid cooled server 1402 through an inlet valve 1408, and return liquid with heat removed from that server 1402 through an outlet valve 1410. In at least one embodiment, rack manifold 1404 can include a number of neural network-enabled secondary liquid distribution control boards 1406. In at least one embodiment, there can be one such control board 1406 for each inlet valve 1408 and outlet valve 1410 for each server. In at least one embodiment, rack 1400 can also include a neural network-enabled rack power distribution unit (PDU) 1412, which can include multiple outlets designed to distribute electric power to computers or networking equipment within rack 1400. In at least one embodiment, there can be a neural network-enabled power distribution control board 1414 associated with each outlet of PDU 1412. In at least one embodiment, sensors can capture information about temperature, air flow, or other such aspects of a computing environment internal and/or external to rack 1400, including internal and/or external to any individual servers 1402 located therein. In at least one embodiment, fluid cooling can remove an amount of heat from servers 1402, but due to factors such as varying load and external temperature fluctuations, temperatures at various locations may change, and may reach or exceed temperature limits at which these devices can continue to operate correctly. In at least one embodiment, an attempt can be made to ensure that temperatures at specific locations remain below an acceptable limit, where those locations may relate to junction temperatures or core temperatures for a processor (e.g., a CPU or GPU), memory module, or power supply.

In at least one embodiment, neural networks in these control boards 1406, 1414 can be tasked to predict values such as coolant flow or air flow, as well as temperatures at these various locations at one or more future points in time. In at least one embodiment, predictions from these networks can be used by a respective board, manifold, PDU, or other such device to make adjustments to ensure appropriate temperature and flow and keep this equipment functioning properly. In at least one embodiment, these adjustments can include adjusting an amount of fluid or air flowing into, or out of, a server or device, as well as a temperature of that fluid or air. In at least one embodiment, this may also include adjusting an amount of power supplied to one or more of these devices. In at least one embodiment, these can include similar adjustments as would be made in other data centers, but can be made based on future predictions instead of observed states, enabling such a system to be proactive instead of reactive. In at least one embodiment, this monitoring can occur continually or at least at regular intervals, in order to ensure proper continued operation.

In at least one embodiment, each neural network in each type of component can be trained specifically for that type of component, and can receive updated network parameters that may be generated as a result of further training or continued learning. In at least one embodiment, inferences generated by individual devices can be shared with other devices in a data center as well, which can help to make more accurate predictions. In at least one embodiment, each control board 1406, 1414 can be a neural network enabled board, ASIC, or other such component. In at least one embodiment, a control board can have components of a general purpose computer, including at least one processor (such as the CPU 1002 of FIG. 10) and memory (such as the main memory 1004 of FIG. 10) with associated circuitry. In at least one embodiment, a Jetson board from NVIDIA Corporation can be used that is a complete system-on-module (SPM), with CPU, GPU, PMIC, DRAM, and flash storage included therein. In at least one embodiment, such a module is also extensible to provide additional functionality or capabilities. In at least one embodiment, each such board can function as a small artificial intelligence (AI) or machine learning enabled computer. In at least one embodiment, multiple such boards can be used in parallel, such as on rack manifold 1404, in order to concurrently process data from multiple high-resolution sensors. In at least one embodiment, these various neural networks can make predictions that can be shared across servers, a rack, or a data center, for example, in order to provide accurate predictions for various locations at one or more future points in time. In at least one embodiment, appropriate adjustments can then be made as appropriate in order to maintain temperatures and other parameters at appropriate levels or values. In at least one embodiment, a liquid distribution control board 1406 may make predictions that can be used to adjust only controls for a relevant flow value, or may share these predictions so that other adjustments can be made as well based at least in part upon these predictions. In at least one embodiment, a control system for a data center may collect predictions from these various boards or networks in order to make adjustments that are more appropriate for an overall data center. In at least one embodiment, adjustments can then be made at a server, rack, pod, data center, or other such level.

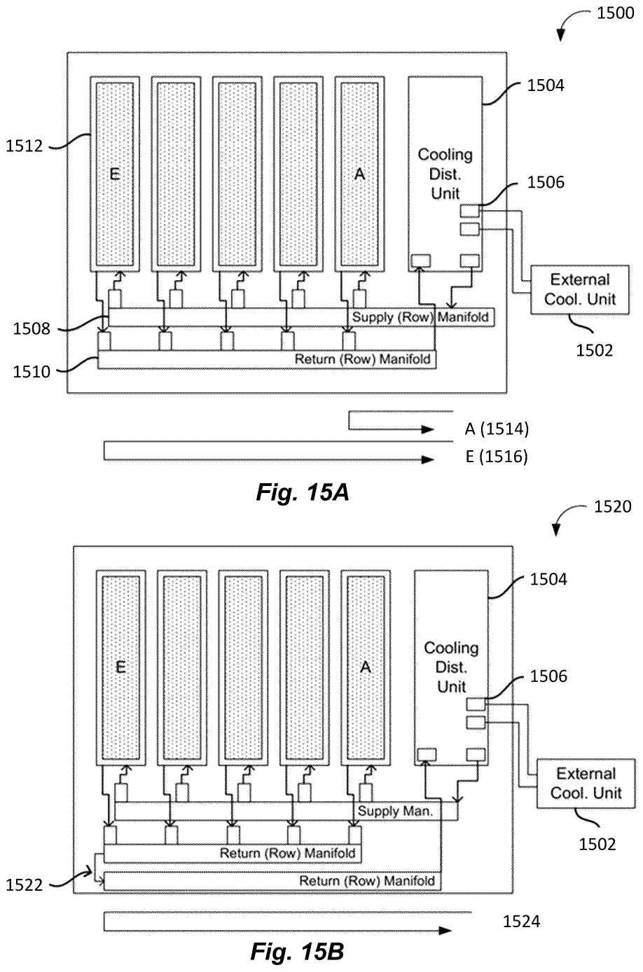

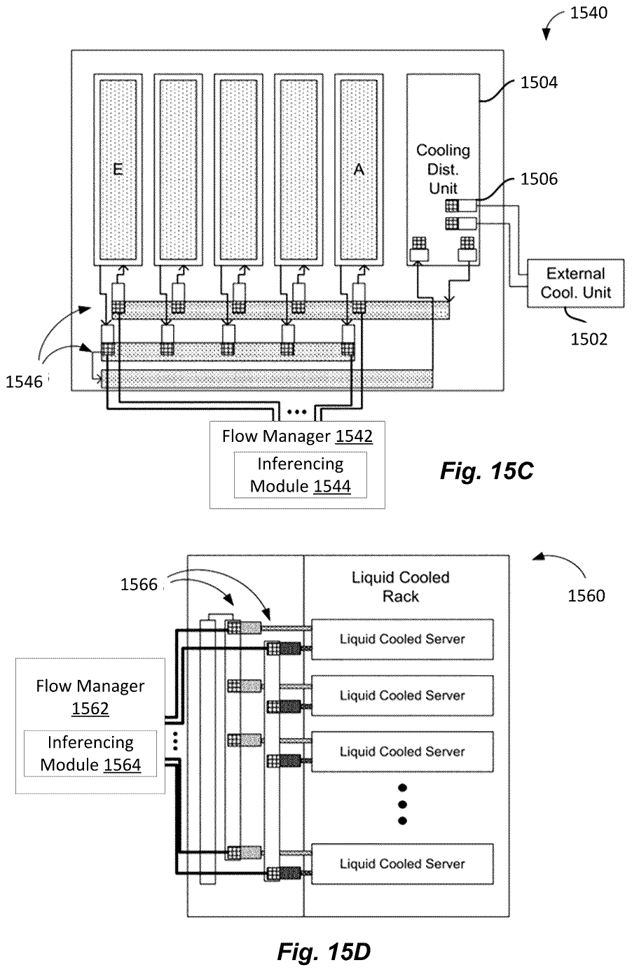

In at least one embodiment, a neural network-enabled approach to liquid cooling of racks at a data center level can utilize components of a system 1500 illustrated in FIG. 15A. In at least one embodiment, an external cooling unit 1502 can provide liquid at a determined temperature to a data center cooling distribution unit 1504. In at least one embodiment, this unit 1504 can include a set of neural network-enabled distribution unit control boards 1506, which can perform inferencing and make adjustments based upon inferred future values. In at least one embodiment, this can include adjusting a temperature of liquid to be received from external cooling unit 1502, or adjusting a flow of that liquid to and/or from that external unit 1502. In at least one embodiment, this can also include adjusting flow into a manifold 1508 for a row of liquid cooled racks 1512, as well as flow into and out of those racks, as may be determined based at least in part upon inferences from neural network-enabled control boards 1510 built into row manifold 1510. In at least one embodiment, there can be different levels of flow into, and out of, different liquid cooled racks. In at least one embodiment, there may also be different flows into individual servers in a rack, such as is described with respect to FIG. 14. In at least one embodiment, a similar approach can be used for an air-cooled data center. In at least one embodiment, temperature and air flow can be measured and predictions made for future values, at times such as 30 seconds, one minute, five minutes, or an hour into our future, which can then enable adjustments to be made to air temperature, air flow, power distribution, and other such aspects. In at least one embodiment, these predictions can be made using various types of input data, such as server load, current temperature, current pressure, flow rate, power consumption, and other pertinent data for various locations within that data center.

In at least one embodiment, these neural network-enabled boards can control an amount of liquid flow, supply, and return at various locations, such as at a rack, server, or GPU-level. In at least one embodiment, these boards can be used to predict, control, and create an optimal solution for such a data center to maintain desired operating conditions, with no loss of equipment or downtime due to temperature issues or thermal events. In at least one embodiment, this can be based on current and anticipated load, as well as measured or detected network conditions. In at least one embodiment, this approach can be applied to other types of devices as well, as may include UPS power supplies. In at least one embodiment, any device with a logic board or component can have this small neural network code injected for these and other such purposes. In at least one embodiment, such a network can tap into all equipment available in a unit or device, such that in a device such as a PDU a board can adjust or cut power completely to a server node, such as where a leak is detected or predicted and relevant equipment may be subject to damage if operation continues. In at least one embodiment, operation can be terminated, or power shut down, gracefully in order to avoid damage. In at least one embodiment, executing programs may instead be terminated in order to at least avoid a loss of data.

In at least one embodiment, a cooling system can utilize a direct return design, as illustrated in FIG. 15A. In at least one embodiment, coolant from a CDU 1504 is directed along a supply manifold 1508 into individual server racks. In at least one embodiment, a first server rack (A) will receive liquid first along this flow, and a last server rack (E) will receive liquid last along this flow. In at least one embodiment, a return manifold 1510 will be used to receive heated liquid passing from these racks and return that heated liquid to CDU 1504. In at least one embodiment, heated liquid returned from first server rack (A) will have a shortest return path, with last server rack (E) having a longest return path. In at least one embodiment, this results in an overall liquid path 1514 for first server rack (A) that is much shorter than an overall liquid path 1516 for last server rack (E) 1516. In at least one embodiment, there can be significant variation is aspects such as pressure and flow throughout a loop of a cooling system. In at least one embodiment, this may include lower pressure near ends of a cooling loop and higher pressure in a middle portion of that loop. In at least one embodiment, such an imbalanced design can result in unacceptable variation in flow rate across a data center or other environment as different path lengths will result in different pressures, temperatures, and other environmental aspects impacting those flows. In at least one embodiment, different amounts of time needed for this liquid to travel along these different paths can also lead to flow variation.

In at least one embodiment, a reverse return-based design can be utilized as illustrated for system 1520 of FIG. 15B. In at least one embodiment, this system includes a reverse return manifold 1522 that receives heated liquid from first server rack (A) first and last server rack (E) last, but instead of directing that flow back directly to CDU 1506 causes liquid to pass from first to last server, or right to left in FIG. 15B, then back through a second portion to CDU 1504. As illustrated, liquid for each server rack will follow a path of similar length 1524, at least through respective manifolds. In at least one embodiment these path lengths may effectively be equal, allowing for slight variations based upon factors such as placement and component type. In at least one embodiment, liquid for each server rack will flow through essentially an entire length of this supply manifold and this return manifold, instead of different portions as in a direct return design of FIG. 15A. In at least one embodiment, this can cause liquid for all server racks to go through these same variations in temperature, pressure, and other environmental parameters encountered throughout a full run of this manifold. In at least one embodiment, such a balanced design can help to reduce variation in flow rate for liquid delivered to different locations throughout this cooling system. In at least one embodiment, this can help to ensure that flow variation is maintained within a desired range, or less than a maximum variation threshold. In at least one embodiment, such a balanced design can help to ensure equal and sufficient liquid is delivered to all servers and racks in a data center by respective cooling components of a liquid cooling system.

In at least one embodiment, all supply and return fluid lines between one or more CDUs and one or more direct-to-chip (D2C) cold plates cooling loops or heat exchangers in an immersive liquid cooled blade can utilize a reverse return, as opposed to a direct return, in various data center collectors, row manifolds, and rack manifolds. In at least one embodiment, electronic valve controls at each of outlets from these collectors, row manifolds, and rack manifolds can have an ability to both monitor and control a flow of primary and/or secondary fluids to, and from, these CDUs leading to cold plates attached to components, such as CPUs, GPUs, and switches, as well as other D2C liquid cooled components and blade immersion servers. In at least one embodiment, a liquid cooling system can utilize a combination of a self-balancing flow design in all primary and secondary loops, along with electronic monitoring and control utilizing AI or machine learning, based at least in part upon data received from various flow rate, pressure, temperature, power, and other environmental or operational sensors. In at least one embodiment, such an approach can provide for improved or optimized liquid distribution liquid cooled components, such as servers and processors, in environments such as data centers

In at least one embodiment, neural network-based flow control can be used with such a design to provide for further variation minimization or flow consistency. In at least one embodiment, a combination of self balancing along with electronics monitoring and control can provide for very balanced and optimized flow of coolant to each of server, rack, processor, or other such component without these components fighting each other and without requiring extensive control schemes. In at least one embodiment, flow controllers can be located at various locations throughout a cooling system, such as may be used to direct coolant into, and out of, components such as racks, servers, and electronic components, where that liquid can be provided using pathways such as row and rack manifolds. In at least one embodiment, these flow controllers can allow for incremental control (e.g., partial opening and closing) to provide for an accurate, self-balancing approach. In at least one embodiment, a self-balancing design with fine adjustable control can provide for accurate balancing of liquid flow across various, if not all, outlets of a liquid cooling system. In at least one embodiment, such an approach can be used to provide a flow of, for example, 50 liters per minute (lpm) with a tolerance, threshold, or variation range of +/−5 lpm, whereas a design without such an approach might have a flow of around 60 lpm at one location and around 40 lpm at another due to differences such as pressure gradients and gravitational effects, which can be an unacceptable flow imbalance across a system.

In at least one embodiment, a control system 1540 can be implemented as illustrated in FIG. 15C. In at least one embodiment, a reverse return row manifold design can be utilized to provide for a balance of pressure and flow across this system. In at least one embodiment, controllable flow valves 1546 can be used at various inlet and/or outlet locations, such a inlets and outlets to individual racks from a row manifold. In at least one embodiment, a flow manager 1542 can receive data from various sensors, devices, or data sources across a relevant environment. In at least one embodiment, this flow manager 1542 can provide at least some of this data as input to one or more neural networks (e.g., deep neural networks (DNNs)) of an inferencing module 1544. In at least one embodiment, sensors and valves can be calibrated for a type of fluid utilized. In at least one embodiment, there may be one flow manager 1542 for an entire data center or environment, or there can be flow managers for individual rows, racks, or servers. In at least one embodiment, neural networks can be utilized at each individual flow control valve as well, as may communicate with one or more separate flow controllers. In at least one embodiment, flow manager 1542 can receive one or more inferences from inferencing module 1544, where those inferences may include adjustments or settings for individual flow control valves. In at least one embodiment, flow manager 152 can then send this or related data or instructions to these individual flow control valves 1546, or other such components, to make small adjustments to help balance flow across this system.

In at least one embodiment, such an approach can be used at a rack level or server level as well as illustrated in system 1560 of FIG. 15D. In at least one embodiment, a liquid cooled rack can have a rack manifold that utilizes a reverse return design, so that liquid path lengths for individual servers of a rack are equivalent as well. In at least one embodiment, a size of this manifold can be much smaller than a size of a corresponding rack, as FIG. 15D illustrates an exploded view for clarity of explanation. In at least one embodiment, a flow manager 1562 can utilize an inferencing module 1564 to determine adjustments to be made to individual flow control valves 1566 within a rack, to balance flow across individual servers in a rack. In at least one embodiment, a flow manager can provide such instructions to flow control valves or components within a server as well, such as may be used to direct coolant for specific cold plates, processors, or other internal server components. In at least one embodiment, use of these intelligent control valves can provide for well-balanced plumbing distribution and controllability. In at least one embodiment, each of these smart control valves 1566 can marginally adjust itself as appropriate, as may be under direction of a flow manager. In at least one embodiment, these flow valves may utilize PID or PIV servo control, where PIV allows for control based on both position and velocity errors.

In at least one embodiment, one or more neural networks can be trained to infer an amount of liquid cooling needed for various components under various circumstances. In at least one embodiment, this may include determining how much additional cooling may be needed for a GPU that goes to 500 Watts of operational power from a more normal 300 Watts, which may require 1.7 lpm instead of 1.0 lpm. In at least one embodiment, this neural network can infer an adjustment to be made to liquid flow for that component, and can enable an accurate adjustment to be made proactively in order to avoid a significant temperature fluctuation from resulting. In at least one embodiment, there may be one or more tables of operations that may correlate factors such as proportional flow rate with power dissipation, which can be used to train these models or used to determine adjustments based on inferred state data. In at least one embodiment, these tables can also be used for different types of components, or different models of a same type of component, in order to account for differences inherent to these components themselves. In at least one embodiment, inferences can be made at different levels of granularity, from an overall data center level to a level of an internal server component such as a GPU. In at least one embodiment, data can be gathered by a component such as a board management controller (BMC) or a server and provided through a networking port to a flow manager, which can send instructions to one or more flow controllers to make one or more appropriate adjustments.

In at least one embodiment, a neural network can predict fluid state at various locations at one or more future times based at least in part upon available information. In at least one embodiment, this can include a snapshot of current information, or may include at least some data over a recent past. In at least one embodiment, these predictions can then be used to adjust aspects such as flow rate. In at least one embodiment, a cooling distribution unit may adjust a flow of liquid or coolant temperature. In at least one embodiment, such equipment can take these predictions and be proactive in order to prevent any undesirable events before they occur. In at least one embodiment, a variety of sensors may provide information about a current state of a computing environment. In at least one embodiment, this may include use of sensors such as temperature sensors, load sensors, flow sensors, or pressure sensors, which can be instantaneously or historically gathered. In at least one embodiment, predictions made based on data from these sensors may be compared to one or more thresholds, ranges, or other operational criteria to determine whether any changes should be made. In at least one embodiment, this can include making an adjustment to prevent an unacceptable temperature rise at a specific location within a data center or other such environment. In at least one embodiment, this may include closing a valve or increasing an amount of coolant flow, adjusting a coolant temperature, or sounding an alarm, among other such remedial actions.

In the packaging of integrated circuit (IC) chips, various packaging schemes are employed, including traditional two-dimensional (2D) integrated circuit (IC) packages as well as the more recently introduced 2.5D IC and 3D IC packages. In 2D IC packages, multiple chips are mounted on a printed circuit board, where high-performance logic, lower-performance logic, memory, and analog/RF functions, and other functional elements are presented as discrete devices in separate chip packages. By contrast, in 2.5D ICs and 3D IC packages, multiple IC chips are mounted on a silicon interposer instead of a conventional package substrate. The silicon interposer, which is typically a silicon wafer, allows very small and high-density conductive traces to be formed between the multiple IC chips because the fabrication processes used to form the conductive traces are the same processes used to form the metal interconnects in the metalization layers of a silicon chip.

Compared to 2.5D IC packages and 3D IC packages, a circuit board with individually packaged chips, such as a 2D IC package, has numerous disadvantages. For example, a 2D IC package is generally larger, heavier, consumes more power, and, because the signals propagate relatively slowly across the circuit board from one chip to another, is slower than an equivalent 2.5D or 3D IC package. Furthermore, a 2D IC package has more possible points of failure, given that the soldered joints on the circuit board are more likely to fail than the electrical connections formed within an interposer. That said, troubleshooting a 2D IC package after the different chips have been mounted on the circuit board is relatively straightforward. In particular, the conductive traces carrying I/O signals between the various chips on the circuit board are easily accessible and therefore can be employed to measure specific I/O signals during troubleshooting.

By contrast, troubleshooting a 2.5D or 3D IC package is far more problematic because the I/O signals transmitted between the different chips typically are embedded in the silicon interposer and are not physically accessible. Furthermore, because 2.5D and 3D IC packages are high-bandwidth and are quite dense, typically implementations can include thousands of conductive traces routed between the different chips. One example of such an implementation is a memory bus residing in between a processor and a high-bandwidth memory chip. In such implementations, even if the traces could be physically accessed through the silicon interposer with a probe, the accurate and reliable selection of a specific conductive trace or combination of conductive traces for the purpose of troubleshooting the IC package would be very difficult, if not impossible.

In at least one embodiment, one or more parallel processor(s) (such as the parallel processing units 1014 of the parallel processing system 1012) incorporate circuitry optimized for graphics and video processing, including, for example, video output circuitry, and constitutes a graphics processing unit (“GPU”). In at least one embodiment, one or more parallel processor(s) incorporate circuitry optimized for general purpose processing. In at least embodiment, components of computing system (such as the computer system 1000) may be integrated with one or more other system elements on a single integrated circuit. For example, in at least one embodiment, one or more parallel processor(s), a memory hub (such as the main memory 1004 of the computer system 1000), one or more processor(s) (such as the CPU 1002 of the computer system 1000), and an I/O hub (which may facilitate communication with, for example, one or more display devices 1006, one or more input devices 1008, and/or a network interface 1022 of a system such as the computer system 1000) can be integrated into a system on chip (SoC) integrated circuit. In at least one embodiment, components of such a computing system can be integrated into a single package to form a system in package (“SIP”) configuration. In at least one embodiment, at least a portion of components of such a computing system can be integrated into a multi-chip module (“MCM”), which can be interconnected with other multi-chip modules into a modular computing system. In at least one embodiment, an I/O subsystem and any display devices are omitted from such a computing system.

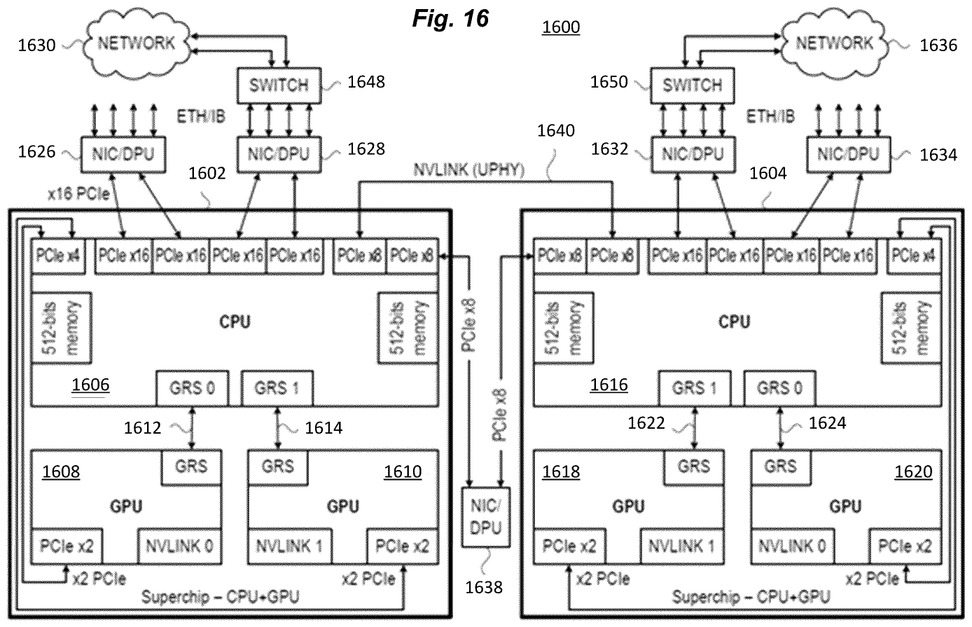

FIG. 16 is a block diagram that schematically illustrates a computing system 1600, e.g., a data center or a High-Performance Computing (HPC) cluster, in accordance with an embodiment that is described herein. System 1600 comprises a plurality of subsystems, e.g. multiple processing devices coupled to each other, multiple network devices, and multiple networks, according to at least one embodiment. Computing system 1600 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1600 and to one or more external networks 1630, 1636. In the present example, system 1600 comprises a packet switch 1648 that connects NIC/DPU 1628 to network 1630, and a packet switch 1650 that connects NIC/DPU 1632 to network 1636.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1600 can include one or more CPUs and one or more GPUs.

FIG. 16 also demonstrates an example architecture of a multi-GPU architecture. As illustrated in the figure, computing system 1600 includes a processing device 1602 with a multi-GPU architecture. In particular, processing device 1602 may be a system-on-chip and includes multiple subsystems such as a CPU 1606, a GPU 1608, and a GPU 1610. CPU 1606 can be coupled to GPU 1608 via a die-to-die (D2D) or chip-to-chip (C2C) interconnect 1612, such as a Ground-Referenced Signaling interconnect (GRS interconnect). CPU 1606 can be coupled to GPU 1610 via a D2D or C2C interconnect 1614. CPU 1606 can also couple to GPU 1608 and GPU 1610 via PCIe interconnects.

CPU 1606 can be coupled to one or more NICs or DPUs, which are coupled to one or more networks. For example, as illustrated in FIG. 16, CPU 1606 is coupled to a first NIC/DPU 1626, which is coupled to a network 1630. CPU 1606 is also coupled to a second NIC/DPU 1628, which is coupled to network 1630 via switch 1648. NIC/DPU 1626 and NIC/DPU 1628 can be coupled to network 1630 over Ethernet (ETH), NVLINK or InfiniBand (IB) connections, for example.

Computing system 1600 also includes a processing device 1604 with a multi-GPU architecture. In particular, processing device 1604 includes multiple subsystems including a CPU 1616, a GPU 1618, and a GPU 1620. CPU 1616 can be coupled to GPU 1618 via an D2D or C2C interconnect 1622. CPU 1616 can be coupled to GPU 1620 via a D2D or C2C interconnect 1624. CPU 1616 can also couple to GPU 1618 and GPU 1620 via PCIe interconnects. CPU 1616 can be coupled to one or more NICs or DPUs, which are coupled to one or more networks. For example, as illustrated in FIG. 16, CPU 1616 is coupled to a first NIC/DPU 1632, which is coupled to a network 1636. CPU 1616 is also coupled to a second NIC/DPU 1634, which is coupled to network 1636 via switch 1650. NIC/DPU 1632 and NIC/DPU 1634 can be coupled to network 1636 over Ethernet (ETH), NVLINK or InfiniBand (IB) connections.

In at least one embodiment, processing device 1602 and processing device 1604 can communicate with each other via a NIC/DPU 1638, such as over PCIe interconnects. Processing device 1602 and processing device 1604 can also communicate with each other over high-bandwidth communication interconnects 1640, such as an NVLink interconnect or other high-speed interconnects. The packet switches in FIG. 16 may comprise, for example, Nvidia Quantum-2 switches. The NICs/DPUs in the figure may comprise, for example, Nvidia Bluefield DPUs.

Cooling systems such as the system 100 described above in connection with FIG. 1—including cooling systems having a pedestal such as the pedestal 128 with a contact surface such as the contact surface 116 and at least one pressure surface such as the pressure surface 120—may be utilized to cool one or more of the components of the system 1600. For example, such a cooling system may be used to cool one or more of the CPUs 1606 and 1616, one or more of the GPUs 1608, 1610, 1618, and 1620, the entire superchip comprising the CPU 1606 and the GPUs 1608 and 1610, and/or comprising the CPU 1616 and the GPUs 1618 and 1620, and or any other physical, heat-producing component of the system 1600.

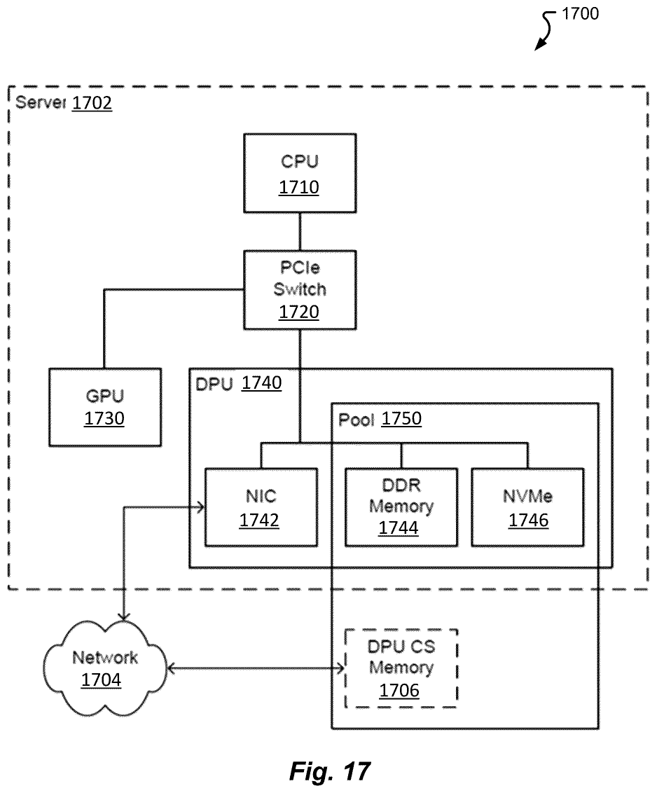

S FIG. 17 illustrates an example computing environment 1700 according to at least one embodiment of the present disclosure in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 1700 may include a server 1702 which may be used to perform HPC workloads, such as AI training or machine learning model training. In an embodiment, the server 1702 may be an application instance or a compute node. The server 1702 may include a CPU 1710 associated with a switch 1720, such as a peripheral component interconnect express (PCIe) switch, which may control at least some data transmission over communication paths interconnecting various components. In an embodiment, the CPU 1710 may include a root complex processor.

The PCIe switch 1720 may also be associated with a GPU 1730 and a DPU 1740, and may transmit data between at least some of the CPU 1710, the G7PU 130, the DPU 1740, and other components. In an embodiment, the PCIe switch 1720 may be associated with more than one GPU or more than one DPU. In another embodiment, the PCIe switch 1720 may be located within the DPU 1740. The PCIe switch 1720 may manage the transfer of at least some data between the CPU 1710, the GPU 1730, and the DPU 1740. In another embodiment, the number of GPUs associated with the PCIe switch 1720 may be equal to the number of DPUs associated with the PCIe switch 1720. In at least one embodiment, the server 1702 may include, without limitation, any number of the CPUs 1710, the PCIe switches 1720, the GPUs 1730, and/or the DPUs 1740, in any combination. For example, in at least one embodiment, server 1702 could include eight, sixteen, thirty-two, and/or more GPUs 1730. In at least one embodiment, communication paths interconnecting various components, including but not limited to the CPU 1710, the PCIe switch 1720, the GPU 1730, and the DPU 1740, in FIG. 17 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 1740 may include a network interface controller (NIC) 1742, a DDR memory 1744, and a non-volatile memory express (NVMe) device 1746. The NIC 1742 may be able to interface with a network 1704, which may also interface with additional NVMe devices available to the DPU 1740, such as over fabric. In an embodiment, the DPU 1740 may not include the NVMe device 1746. In another embodiment, the NVMe device 1746 may be located on the server 1702 and not on the DPU 1740. In yet another embodiment, the computing environment 1700 may include more than one of the NVMe device 1746, such as a first NVMe device in the DPU 1740 and a second first NVMe device on the server 1702 an associated directly with the PCIe switch 1720. In an embodiment, the DPU 1740 may not include the DDR memory 1744 and may include a computational storage services (CSS) in place of, or in addition to, the DDR memory 1744. For example, the computing environment 1700 may include DPU computational storage (CS) memory 1706 available to the DPU 1740 as part of the CSS. The network 1704 may be able to interface with the DPU CS memory 1706 through the NIC 1742, according to any suitable interface protocol, such as remote direct memory access (RDMA) over Ethernet, InfiniBand, Fiber Channel, etc.

The total memory of the computing environment 1700 available for data storage may be expanded through the use of the DPU 1740 on nodes of the system. The DPU 1740 may have access to a pool 1750 of memory already available to the server 1702, such as double data rate (DDR) memory, on-board NVMe devices, NVMe devices over fabric, and CS. The pool 1750 of memory may include at least one of the DDR memory 1744, NVMe 1746, and the DPU CS memory 1706. The DPU 1740 may also be able to access the available memory of other DPUs as part of the pool 1750, and other DPUs may be able to access the available memory of DPU 1740, such as the pool 1750. This available memory can be accessed and utilized for data storage, without the addition of compute resources, such as compute nodes, which would be required using other solutions. The available pool 1750 accessible to the DPU 1740 may be provisioned for the server 1702 to expand the total memory available for data storage, such as to reduce the data storage load on the CPU 1710 or the GPU 1730, which can instead increase the utilization of their memory for processing. For example, during training of an AI, the model states, residual states, activation functions, and checkpoints can be stored, or offloaded, on the pool 1750 accessible to the DPU 1740.

Embodiments of the present disclosure may comprise any suitable material known in the art (e.g., carbon steel, aluminum, polymers, ceramics, and the like), particularly materials possessing high thermal conductivity. By way of example, components as described herein may be created by an extrusion and/or machine process. In such an example, a single body of fixed cross-sectional area may be produced by an extrusion process.

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components (e.g., components of printed circuit boards, transceivers, cables, etc.) may be used in conjunction with components described herein. Therefore, it is to be understood that the disclosures are not to be limited to the specific embodiments disclosed and that modifications and other embodiments are intended to be included within the scope of the appended claims.

It is to be appreciated that any feature described herein can be claimed in combination with any other feature(s) as described herein, regardless of whether the features come from the same described embodiment.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A cooling system, comprising:
a pedestal to support a semiconductor package, the pedestal comprising:
a first geometry having a contact surface; and
at least one second geometry having a pressure surface, the pressure surface offset from the contact surface.

2. The cooling system of claim 1, wherein the pedestal comprises two second geometries, each having a pressure surface offset from the contact surface.

3. The cooling system of claim 1, wherein the contact surface comprises a convex or concave surface.

4. The cooling system of claim 1, wherein the pressure surface is parallel to the contact surface.

5. The cooling system of claim 1, wherein the pressure surface is raised above the contact surface.

6. The cooling system of claim 1, wherein the pressure surface comprises a convex or concave surface.

7. The cooling system of claim 1, wherein the contact surface has a rectangular perimeter.

8. The cooling system of claim 1, wherein the pressure surface has a circular perimeter.

9. The cooling system of claim 1, wherein the pressure surface has a rectangular perimeter.

10. The cooling system of claim 1, wherein the pressure surface has a pressure surface area, the contact surface has a contact surface area, and the pressure surface area is between two percent and fifteen percent of the contact surface area.

11. The cooling system of claim 1, wherein the pressure surface is offset from the contact surface by no more than 100 microns.

12. The cooling system of claim 1, wherein the pressure surface comprises a midpoint that is equidistant from opposite points on a perimeter of the contact surface.

13. The cooling system of claim 1, wherein the contact surface and the pressure surface are covered in a thermal interface material.

14. A cooling system comprising:
a plurality of cooling elements; and
a plate in thermal communication with at least one of the plurality of cooling elements, the plate comprising:
a contact surface; and
a pressure surface on a protrusion extending from the contact surface.

15. The cooling system of claim 14, wherein a height of the pressure surface above the contact surface is less than five percent of a height of the plate.

16. The cooling system of claim 14, wherein the contact surface has a square geometry and the pressure surface has a circular geometry.

17. The cooling system of claim 14, further comprising:
a semiconductor package mounted to the plate; and
a thermal interface material positioned between the semiconductor package and the plate.

18. The cooling system of claim 14, wherein a pressure applied to the semiconductor package by the pressure surface substantially counteracts thermal-mechanical deformations in the semiconductor package when the semiconductor package is in use.

19. A dual-geometry cooling plate comprising:
a first portion having a first geometry and a contact surface; and
a second portion having a second geometry and a pressure surface offset from the contact surface,
wherein the first portion and the second portion form an integral cooling plate.

20. The dual-geometry cooling plate of claim 19, wherein milling is used to generate the second geometry, wherein the first geometry is a plate having a thickness of no more than 2000 microns, and the second geometry is a cylinder having a height of no more than 50 microns, wherein the second portion extends from the first portion, and wherein the first geometry is different than the second geometry.
